(19) United States
(12) Patent Application Publication
(10) Pub. No.: US 2025/0185295 A1
(43) Pub. Date: Jun. 5, 2025

(54) SEMICONDUCTOR DEVICE INCLUDING A LOWER INSULATING PATTERN

(71) Applicant: SAMSUNG ELECTRONICS CO., LTD., SUWON-SI (KR)

(72) Inventors: KI HWAN KIM, Suwon-si (KR); UNKI KIM, Suwon-si (KR); CHANYOUNG KIM, Suwon-si (KR); JEONGHO YOO, Suwon-si (KR); INGYU JANG, Suwon-si (KR); SUJIN JUNG, Suwon-si (KR); SUNGKEUN LIM, Suwon-si (KR)

(21) Appl. No.: 18/931,250

(22) Filed: Oct. 30, 2024

(30) Foreign Application Priority Data
Dec. 4, 2023 (KR) 10-2023-0173759

(51) Int. Cl. H01L 29/417; H01L 21/285; H01L 23/528; H01L 29/06; H01L 29/08; H01L 29/423; H01L 29/66; H01L 29/775; H01L 29/786

(52) U.S. Cl. CPC H10D 30/6729; H01L 21/28518; H01L 23/5286; H10D 30/014; H10D 30/43; H10D 30/6735; H10D 30/6757; H10D 62/121; H10D 62/151; H10D 64/017

(57) ABSTRACT

A semiconductor device including a substrate having an insulating pattern, a channel pattern disposed on the insulating pattern a source/drain pattern disposed adjacent to the plurality of semiconductor patterns, a gate electrode disposed on the plurality of semiconductor patterns, a lower power line disposed in a lower portion of the substrate, a lower insulating pattern disposed between the source/drain pattern and the insulating pattern, a backside active contact disposed below the source/drain pattern, and a backside silicide pattern disposed between the source/drain pattern and the backside active contact. In one aspect, the backside active contact penetrates the substrate and the lower insulating pattern and is electrically connects the lower power line and the source/drain pattern. In one aspect, the backside active contact and the backside silicide pattern are vertically overlapped with the doping layer.

### CROSS-REFERENCE TO RELATED APPLICATION

This U.S. non-provisional patent application claims priority under 35 U.S.C. § 119 to Korean Patent Application No. 10-2023-0173759, filed on Dec. 4, 2023, in the Korean Intellectual Property Office, the disclosure of which is incorporated by reference herein in its entirety.

### BACKGROUND OF THE INVENTION

The present disclosure relates to a semiconductor device, and in particular, to a semiconductor device including a field effect transistor.

A semiconductor device includes an integrated circuit comprising metal-oxide-semiconductor field-effect transistors (MOS-FETs). With an increasing demand for a semiconductor device with a small pattern size and a reduced design rule, the MOS-FETs are scaled down. The scale-down of the MOS-FETs may lead to deterioration in operational properties of the semiconductor device. A variety of studies conducted to overcome technical limitations associated with the scale-down of the semiconductor device. In some cases, semiconductor devices with high performance are manufactured.

### SUMMARY

A semiconductor device including a substrate having an insulating pattern, a channel pattern disposed on the insulating pattern. In one aspect, the channel pattern includes a plurality of semiconductor patterns vertically stacked and spaced apart from each other. The semiconductor device further includes a source/drain pattern disposed adjacent to the plurality of semiconductor patterns, a gate electrode disposed on the plurality of semiconductor patterns, and a lower power line disposed in a lower portion of the substrate. In one aspect, a bottom surface of the lower power line is coplanar with a bottom surface of the substrate. The semiconductor device further includes a lower insulating pattern disposed between the source/drain pattern and the insulating pattern, a backside active contact disposed below the source/drain pattern, and a backside silicide pattern disposed between the source/drain pattern and the backside active contact. In one aspect, the backside active contact penetrates the substrate and the lower insulating pattern and is electrically connects the lower power line and the source/drain pattern. In one aspect, the source/drain pattern includes a buffer layer disposed on side surfaces of the plurality of semiconductor patterns and the gate electrode, a barrier layer disposed on an inner side surface of the buffer layer, and a doping layer filling a space enclosed by the barrier layer. In one aspect, the backside active contact and the backside silicide pattern are vertically overlapped with the doping layer.

A semiconductor device includes a substrate, a lower power line disposed in a lower portion of the substrate, a lower insulating pattern disposed on the substrate, a source/drain pattern disposed on the lower insulating pattern, and a backside active contact disposed below the source/drain pattern. In one aspect, the backside active contact penetrates the substrate and electrically connects the lower power line and the source/drain pattern. In one aspect, the source/drain pattern includes a buffer layer disposed on the lower insulating pattern, and the buffer layer has a first doping concentration. The semiconductor device further includes a barrier layer disposed on an inner side surface of the buffer layer, where the barrier layer has a second doping concentration, and a doping layer filling a space enclosed by the buffer layer, where the doping layer has a third doping concentration. In one aspect, the backside active contact is electrically connected to the doping layer, and the third doping concentration is higher than the first doping concentration and the second doping concentration.

A semiconductor device including an insulating substrate, a channel pattern disposed on the insulating substrate, where the channel pattern includes a plurality of semiconductor patterns vertically stacked and spaced apart from each other, and a pair of source/drain patterns connected to the channel pattern, where the pair of source/drain patterns comprising a first sub-source/drain pattern and a second sub-source/drain pattern. The semiconductor device further includes a first lower insulating pattern disposed below the first sub-source/drain pattern, a second lower insulating pattern disposed below the second sub-source/drain pattern, an etch stop layer disposed on the second sub-source/drain pattern, and a gate electrode disposed on the channel pattern. In one aspect, the gate electrode comprises inner electrodes interposed between adjacent ones of the plurality of semiconductor patterns and an outer electrode disposed on an uppermost one of the semiconductor patterns. The semiconductor device further includes a gate insulating layer interposed between the gate electrode and the channel pattern, a gate spacer disposed on a side surface of the gate electrode, a gate capping pattern disposed on a top surface of the gate electrode, an interlayer insulating layer covering the pair of source/drain patterns, the gate capping pattern, and the etch stop layer, and an active contact disposed on the insulating substrate, where the active contact penetrates the interlayer insulating layer and is electrically connected to the first sub-source/drain pattern. The semiconductor device further includes a first metal layer disposed on the interlayer insulating layer, where the first metal layer comprises a first interconnection line electrically connected to the active contact, a second metal layer disposed on the first metal layer, where the second metal layer comprises a second interconnection line electrically connected to the first metal layer, and a lower power line disposed in a lower portion of the insulating substrate, where a bottom surface of the lower power line is coplanar with a bottom surface of the insulating substrate. The semiconductor device further includes a backside active contact disposed below the second sub-source/drain pattern, where the backside active contact penetrates the insulating substrate and electrically connects the lower power line to the second sub-source/drain pattern, and a backside silicide pattern disposed between the second sub-source/drain pattern and the backside active contact. In one aspect, the first lower insulating pattern is extended from a bottom surface of the first sub-source/drain pattern to a side surface of the lowermost one of the inner electrodes, and the second lower insulating pattern is extended from an upper portion of a side surface of the backside active contact to a side surface of the lowermost one of the inner electrodes.

### BRIEF DESCRIPTION OF THE DRAWINGS

FIGS. 1, 2, and 3 are example diagrams illustrating logic cells of a semiconductor device according to an embodiment of the present inventive concept.

FIG. 4 is a plan view illustrating a semiconductor device according to an embodiment of the present inventive concept.

FIGS. 5A, 5B, 5C, and 5D are cross-sectional views taken along lines A-A′, B-B′, C-C′, and D-D′, respectively, of FIG. 4.

FIG. 6A is an enlarged cross-sectional view illustrating an example of a portion ‘M’ in FIG. 5A.

FIGS. 6B and 6C are graphs showing a concentration distribution based on a width or height of a source/drain pattern.

FIG. 7 is an enlarged cross-sectional view illustrating an example of the portion ‘M’ of FIG. 5A.

FIGS. 8A and 8B are enlarged cross-sectional views illustrating examples of portions shown in FIGS. 6A and 7, respectively.

FIGS. 9A, 9B, 10A, 10B, 11A, 11B, 11C, 12A, 12B, 12C, 13A, 13B, 13C, 13D, 14A, 14B, 14C, 14D, 15A, 15B, 15C, 15D, 16A, 16B, 16C, 17A, 17B, 17C, 18A, 18B, and 18C are cross-sectional views illustrating a method of fabricating a semiconductor device, according to an embodiment of the present inventive concept.

FIGS. 19, 20, 21, 22, 23, and 24 are enlarged cross-sectional views illustrating a process of forming a source/drain pattern in a portion ‘N’ of FIG. 12A.

### DETAILED DESCRIPTION

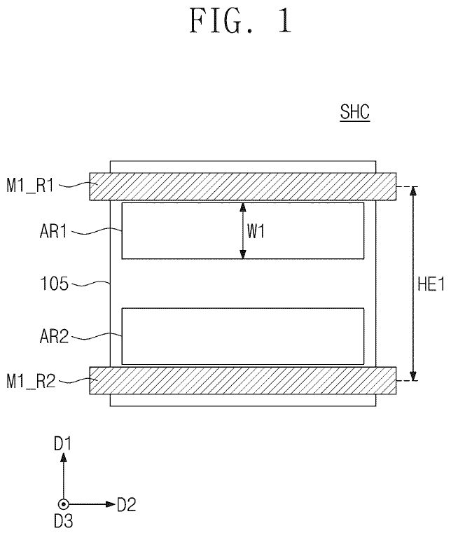

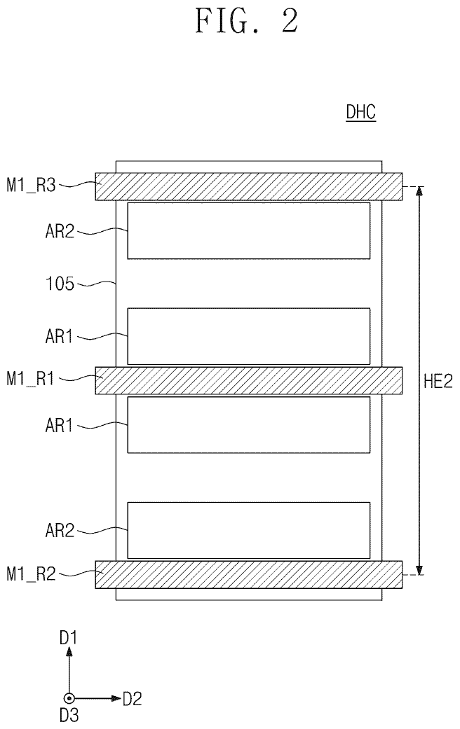

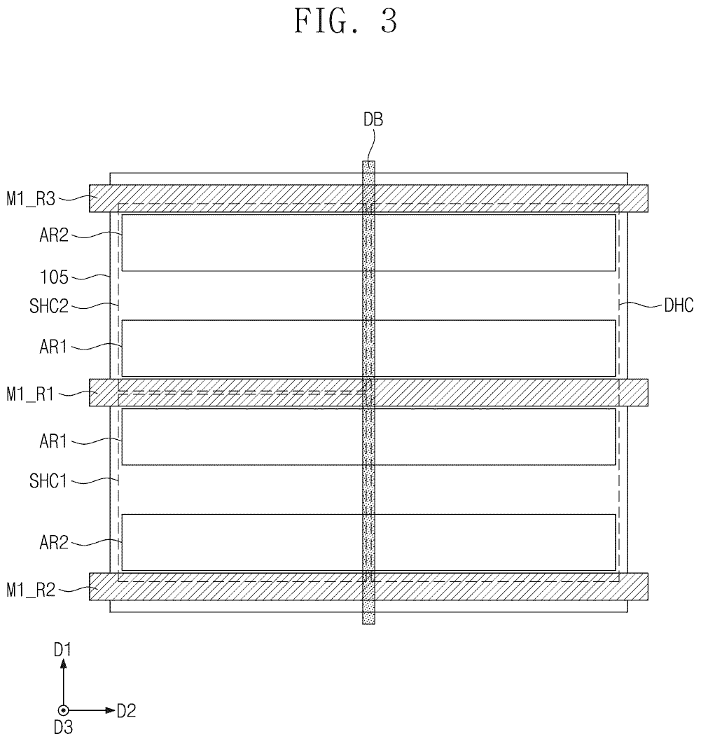

FIGS. 1 to 3 are example diagrams illustrating logic cells of a semiconductor device according to an embodiment of the present inventive concept. For example, FIG. 1 illustrates a single height cell SHC. FIG. 2 illustrates a double height cell DHC. FIG. 3 illustrates logic cells including a first single height cell SHC1, a second single height cell SHC2, and a double height cell DHC.

Referring to FIG. 1, a single height cell SHC is provided. For example, a first power line M1_R1 and a second power line M1_R2 may be disposed on a substrate 105. The first power line M1_R1 may be a conduction path connected to a source voltage VSS (e.g., a ground voltage). The second power line M1_R2 may be a conduction path connected to a drain voltage VDD (e.g., a power voltage).

The single height cell SHC may be represented as the space between the first power line M1_R1 and the second power line M1_R2. The single height cell SHC may include a first active region AR1 and a second active region AR2. In some cases, the first active region AR1 and the second active region AR2 are disposed towards a center of the single height cell SHC. In some cases, the first power line M1_R1 and the second power line M1_R2 are disposed away from the center of the single height cell SHC. One of the first active region AR1 and second active region AR2 may be a PMOSFET region, and the other may be an NMOSFET region. For example, the first active region AR1 may be a NMOSFET region and the second active region AR2 may be a PMOSFET region, or vice versa. In some cases, the single height cell SHC may have a CMOS structure provided between the first power line M1_R1 and second power line M1_R2.

Each of the first active region AR1 and second active region AR2 may have an active region width W1 measured in a first direction D1. A length of the single height cell SHC measured in the first direction D1 may be represented as a single height cell height HE1. The single height cell height HE1 may be substantially equal to a distance (e.g., a pitch) between the first power line M1_R1 and second power line M1_R2.

The single height cell SHC may form a single logic cell. In the present specification, the logic cell may include a logic device (e.g., AND, OR, XOR, XNOR, inverter, and so forth), which is configured to execute a specific function. For example, the logic cell may include transistors including the logic device and interconnection lines connecting the transistors to each other.

Referring to FIG. 2, a double height cell DHC is disposed on substrate 105. For example, a first power line M1_R1, a second power line M1_R2, and a third power line M1_R3 may be disposed on the substrate 105. The first power line M1_R1 may be disposed between the second power line M1_R2 and the third power line M1_R3. The third power line M1_R3 may be a conduction path connected to the source voltage VSS (e.g., a ground voltage).

The double height cell DHC may be represented as the space between the second power line M1_R2 and the third power line M1_R3. For example, the outer perimeters of the double height cell DHC along the second direction D2 may be represented by the second power line M1_R2 and the third power line M1_R3. The double height cell DHC may include a pair of first active regions AR1 and a pair of second active regions AR2.

One of the second active regions AR2 may be disposed adjacent to the second power line M1_R2. The other of the second active regions AR2 may be disposed adjacent to the third power line M1_R3. In some cases, the pair of the second active regions AR2 is disposed within the perimeter of the double height cell DHC. The pair of the first active regions AR1 may be disposed adjacent to the first power line M1_R1. When viewed in a plan view, the first power line M1_R1 may be disposed between the pair of the first active regions AR1.

A length of the double height cell DHC measured in the first direction D1 may be represented as a double height cell height HE2. The length of the double height cell height HE2 may be about two times the length of the single height cell height HE1 described with reference to FIG. 1. In an embodiment, the pair of the first active regions AR1 of the double height cell DHC may be combined as one active region.

In an embodiment, the double height cell DHC may be referred to as a multi-height cell. For example, the multi-height cell may include a triple height cell having a cell height that is about three times the height (or length measured in the first direction D1) of the single height cell SHC. In some cases, the triple height cell may have an additional power line, the first power line M1_R1, the second power line M1_R2, or the third power line M1_R3. In some cases, the triple height cell may have an additional set of first active region AR1 and second active region AR2.

Referring to FIG. 3, a first single height cell SHC1, a second single height cell SHC2, and a double height cell DHC may be two-dimensionally arranged on the substrate 105. For example, the first single height cell SHC1 may be disposed adjacent to the second single height cell SHC2 along the first direction D1. For example, the double height cell DHC and be disposed adjacent to the first single height cell SHC1 and the second single height cell SHC2 along the second direction D2. The first single height cell SHC1 may be disposed between the first power line M1_R1 and the second power line M1_R2. The second single height cell SHC2 may be disposed between the first power line M1_R1 and the third power line M1_R3. In some cases, the first single height cell SHC1 and the second single height cell SHC2 may share the first power line M1_R1. In some cases, the first power line M1_R1 of the first single height cell SHC1 and first power line M1_R1 of the second single height cell SHC2 may be disposed adjacent to and connected to each other.

In some cases, the double height cell DHC may be disposed between the second power line M1_R2 and the third power line M1_R3. The double height cell DHC may be disposed adjacent to the first single height cell SHC1 and the second single height cell SHC2 along the second direction D2. In some cases, the first single height cell SHC1 and the double height cell DHC may share the first power line M1_R1 and the second power line M1_R2. In some cases, the second single height cell SHC2 and the double height cell DHC may share the first power line M1_R1 and the third power line M1_R3.

A division structure DB may be disposed between the first single height cell SHC1 and the double height cell DHC and between the second single height cell SHC2 and the double height cell DHC. The active region (e.g., the first active region AR1 and the second active region AR2) of the double height cell DHC may be electrically separated from the corresponding active region of each of the first single height cell SHC1 and the second single height cell SHC2 by the division structure DB.

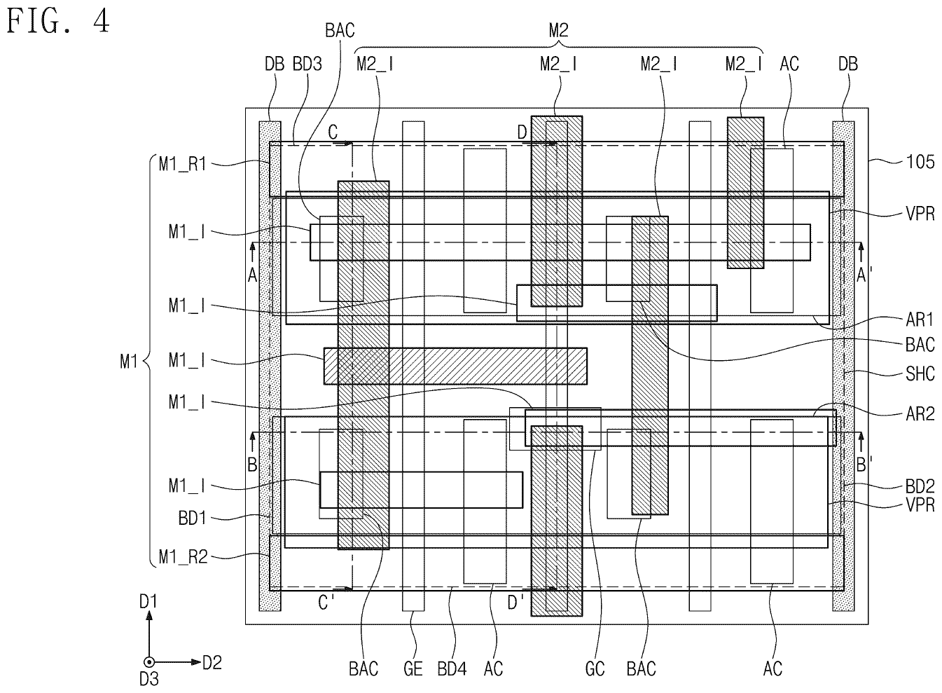

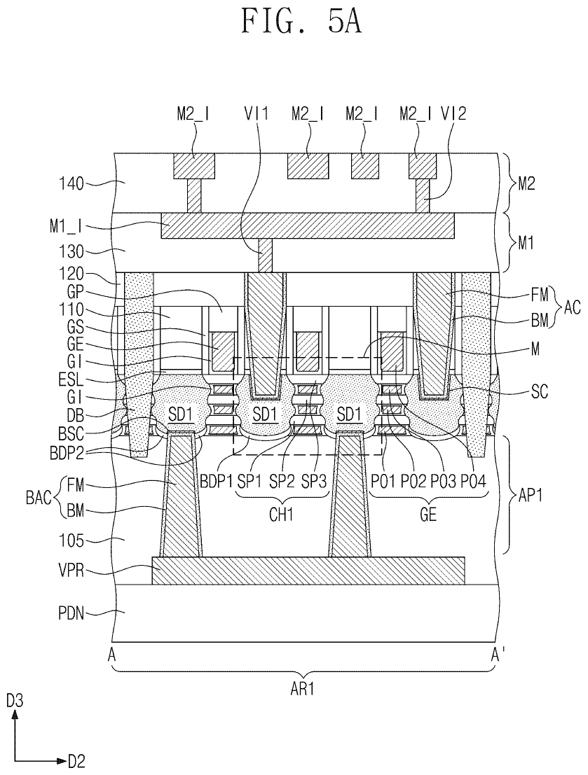

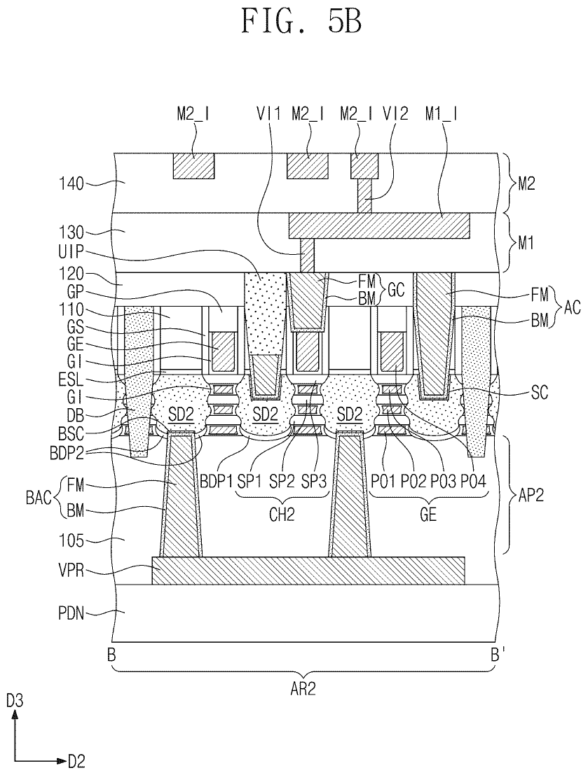

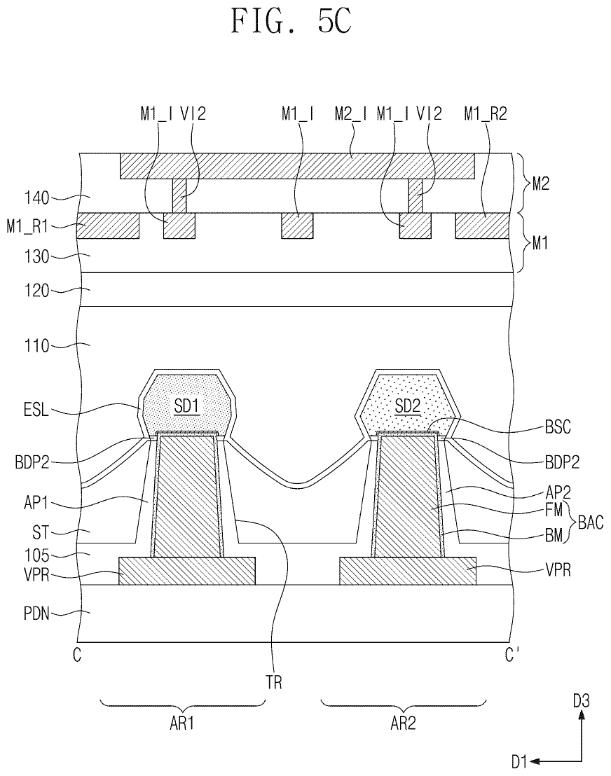

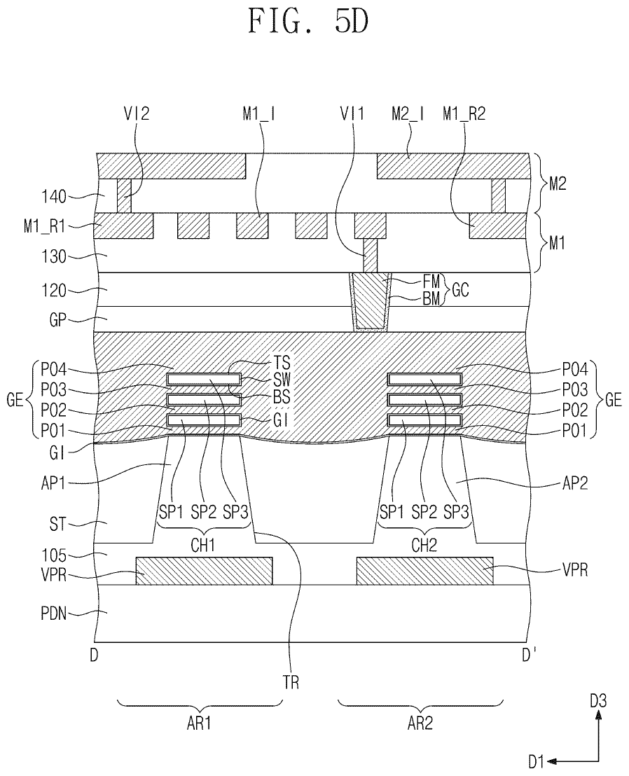

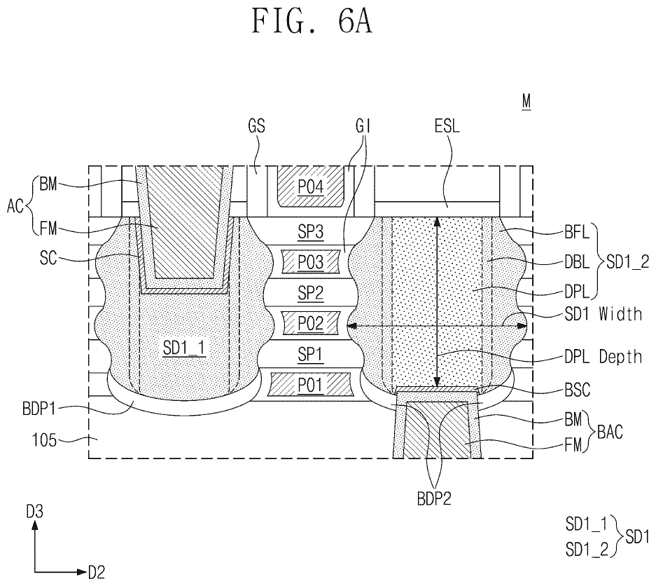

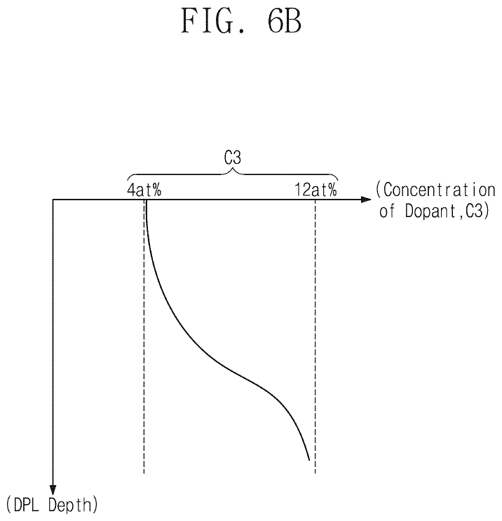

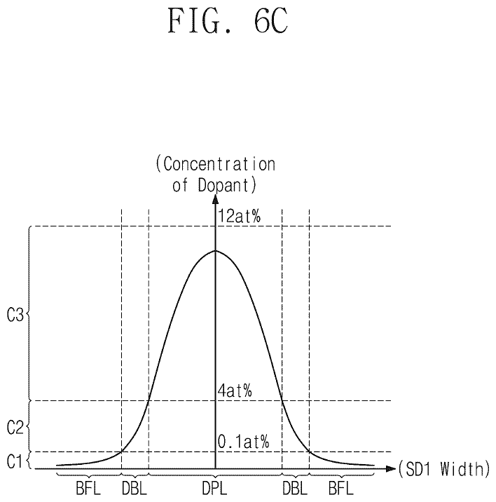

FIG. 4 is a plan view illustrating a semiconductor device according to an embodiment of the present inventive concept. FIGS. 5A, 5B, 5C, and 5D are cross-sectional views taken along lines A-A′, B-B′, C-C′, and D-D′ of FIG. 4, respectively. FIG. 6A is an enlarged cross-sectional view illustrating an example of a portion ‘M’ in FIG. 5A, and FIGS. 6B and 6C are graphs showing a concentration distribution based on a width or height of a source/drain pattern. The semiconductor device of FIGS. 4 and 5A to 5D may be an example of the single height cell SHC of FIG. 1.

Referring to FIGS. 4 and 5A to 5D, the single height cell SHC may be disposed on the substrate 105. In some cases, the substrate is disposed on a power delivery network layer PDN. Logic transistors including a logic circuit may be disposed on the single height cell SHC. In some cases, the substrate 105 may include a silicon-based insulating layer. In an embodiment, the substrate 105 may be an insulating substrate. In some cases, for example, the substrate 105 may include a silicon oxide layer, a silicon nitride layer, or a silicon oxynitride layer. A backside active contact BAC, which is described below, may be disposed in the substrate 105.

The substrate 105 may include the first active region AR1 and the second active region AR2. Each of the first active region AR1 and the second active region AR2 may be extended along the second direction D2. In an embodiment, the first active region AR1 may be an NMOSFET region, and the second active region AR2 may be a PMOSFET region.

A first insulating pattern AP1 and a second insulating pattern AP2 may be represented as a trench TR formed in the substrate 105. The first insulating pattern AP1 may be disposed on the first active region AR1, and the second insulating pattern AP2 may be disposed on the second active region AR2. The first and second insulating patterns AP1 and AP2 may be extended along the second direction D2.

A device isolation layer ST may be disposed in the trench TR, where the device isolation layer ST is formed on the substrate 105. For example, the device isolation layer ST may fill the trench TR. The device isolation layer ST may include a silicon oxide layer. The device isolation layer ST might not cover a first channel pattern CH1 and a second channel pattern CH2.

The first channel pattern CH1 may be disposed on the first insulating pattern AP1. The second channel pattern CH2 may be disposed on the second insulating pattern AP2. Each of the first channel pattern CH1 and second channel pattern CH2 may include a first semiconductor pattern SP1, a second semiconductor pattern SP2, and a third semiconductor pattern SP3 sequentially stacked. The first, second, and third semiconductor patterns SP1, SP2, and SP3 may be spaced apart from each other in a vertical direction (i.e., a third direction D3).

Each of the first, second, and third semiconductor patterns SP1, SP2, and SP3 may include silicon (Si), germanium (Ge), silicon-germanium (SiGe), or a combination thereof. For example, each of the first, second, and third semiconductor patterns SP1, SP2, and SP3 may include crystalline silicon (e.g., single crystalline silicon). In an embodiment, the first, second, and third semiconductor patterns SP1, SP2, and SP3 may be a stack of nanosheets.

A plurality of first source/drain patterns SD1 may be disposed on the first insulating pattern AP1. A plurality of first recesses may be formed in an upper portion of the first insulating pattern AP1. The first source/drain patterns SD1 may be provided in the first recesses, respectively. In an embodiment, the first source/drain patterns SD1 may include impurity regions of a first conductivity type (e.g., n-type). The first channel pattern CH1 may be interposed between each pair of the first source/drain patterns SD1. For example, each pair of the first source/drain patterns SD1 may be connected to each other by the stacked first, second, and third semiconductor patterns SP1, SP2, and SP3.

A plurality of second source/drain patterns SD2 may be disposed on the second insulating pattern AP2. A plurality of second recesses may be formed in an upper portion of the second insulating pattern AP2. The second source/drain patterns SD2 may be provided in the second recesses, respectively. In an embodiment, the second source/drain patterns SD2 may include impurity regions of a second conductivity type (e.g., p-type). The second channel pattern CH2 may be interposed between a pair of the second source/drain patterns SD2. For example, each pair of the second source/drain patterns SD2 may be connected to each other by the stacked first, second, and third semiconductor patterns SP1, SP2, and SP3.

The first and second source/drain patterns SD1 and SD2 may include epitaxial patterns which are formed by a selective epitaxial growth (SEG) process. In an embodiment, a top surface of each of the first and second source/drain patterns SD1 and SD2 may be coplanar with a top surface of the third semiconductor pattern SP3. For example, the top surface of each of the first and second source/drain patterns SD1 and SD2 may be at substantially the same level as the top surface of the third semiconductor pattern SP3. In an embodiment, the top surface of each of the first and second source/drain patterns SD1 and SD2 may be higher than the top surface of the third semiconductor pattern SP3.

In an embodiment, the first source/drain patterns SD1 may include a first semiconductor element (e.g., silicon (Si)). The second source/drain patterns SD2 may include a second semiconductor material (e.g., silicon-germanium (SiGe)) having a lattice constant greater than silicon (Si). Accordingly, the pair of the second source/drain patterns SD2 may exert a compressive stress on the second channel pattern CH2 therebetween.

In some cases, each of the second source/drain patterns SD2 may include a first layer and a second layer disposed on the first layer. A volume of the second layer may be larger than a volume of the first layer. Each of the first and second layers may include silicon-germanium (SiGe) compound. For example, the first layer may include a relatively low concentration of germanium (Ge) in comparison to the second layer. In an embodiment, the first layer may include silicon (Si) element. The germanium concentration of the first layer may range from 0 at % to 30 at %.

In some cases, the second layer may include a relatively high concentration of germanium (Ge) in comparison to the first layer. In an embodiment, the germanium concentration of the second layer may range from 30 at % to 70 at %. The germanium concentration of the second layer may increase as a height of the second layer measured in in the third direction D3 increases. For example, the second layer adjacent to the first layer may have a germanium concentration of about 40 at %, and an upper portion of the second layer may have a germanium concentration of about 60 at %.

Each of the first and second layers may include impurities (e.g., boron (B), gallium (Ga), or indium (In)), and as a result, the second source/drain pattern SD2 has a p-type conductivity. An impurity concentration of each of the first and second layers may range from 1E18 atom/cm³ to 5E22 atom/cm³. The impurity concentration of the second layer may be higher than the impurity concentration of the first layer.

The first layer may protect the second layer in a subsequent process of replacing sacrificial layers SAL with first inner electrode PO1, second inner electrode PO2, and third inner electrode PO3 of a gate electrode GE. For example, the first layer may prevent an etchant material, which is a material used to remove the sacrificial layers SAL, from entering and etching the second layer.

Each of the first source/drain patterns SD1 may include silicon (Si). The first source/drain pattern SD1 may include impurities (e.g., phosphorus (P), arsenic (As), or antimony (Sb)), and as a result, the first source/drain pattern SD1 has an n-type conductivity. Further detail on the first source/drain patterns SD1 is described with reference to FIGS. 6A to 6C.

In an embodiment, a side surface of each of the first and second source/drain patterns SD1 and SD2 may have an uneven or embossing shape. For example, the side surface of each of the first and second source/drain patterns SD1 and SD2 may have a wavy profile. The side surface of each of the first and second source/drain patterns SD1 and SD2 may protrude toward the first, second, and third inner electrodes PO1, PO2, and PO3 of the gate electrode GE.

Lower insulating patterns BDP1 and BDP2 may be disposed below the first and second source/drain patterns SD1 and SD2. The lower insulating patterns BDP1 and BDP2 may be extended from bottom surfaces of the first and second recesses to side surfaces of the first and second recesses. The lower insulating patterns BDP1 and BDP2 may include an insulating material. For example, the lower insulating patterns BDP1 and BDP2 may include SiNₓ or SiON. Further detail on the lower insulating patterns BDP1 and BDP2 is described with reference to FIG. 6A.

An etch stop layer ESL may be disposed on each of the first and second source/drain patterns SD1 and SD2. Referring to FIG. 5C, the etch stop layer ESL may cover the device isolation layer ST, the lower insulating pattern BDP2, and the first and second source/drain patterns SD1 and SD2. The etch stop layer ESL may be formed to have a uniform thickness. For example, the thickness measured in the third direction D3 may range from 1 nm to 5 nm.

The etch stop layer ESL may include the same material as the lower insulating patterns BDP1 and BDP2. In an embodiment, the etch stop layer ESL may include SiN, SiCN, SiOCN, SiBN, SiBC, or any combinations thereof. A hardness of the etch stop layer ESL may be greater than a hardness of each of the first and second lower insulating patterns BDP1 and BDP2. Alternatively, the hardness of the etch stop layer ESL may be substantially equal to the hardness of each of the first and second lower insulating patterns BDP1 and BDP2.

The gate electrodes GE may be disposed on the first and second channel patterns CH1 and CH2. Each of the gate electrodes GE may be extended in the first direction D1 to intersect the first and second channel patterns CH1 and CH2. Each of the gate electrodes GE may be vertically overlapped with the first and second channel patterns CH1 and CH2. The gate electrodes GE may be arranged at a first pitch in the second direction D2.

In some embodiments, the gate electrode GE may include a first inner electrode PO1, a second inner electrode PO2, a third inner electrode PO3, and an outer electrode PO4. In some cases, the first inner electrode PO1 the gate electrode GE may be interposed between each of the first and second insulating patterns AP1 and AP2 and the first semiconductor pattern SP1. The second inner electrode PO2 of the gate electrode GE may be interposed between the first semiconductor pattern SP1 and the second semiconductor pattern SP2. The third inner electrode PO3 of the gate electrode GE may be interposed between the second semiconductor pattern SP2 and the third semiconductor pattern SP3. The outer electrode PO4 of the gate electrode GE may be disposed on the third semiconductor pattern SP3. In some cases, each inner electrode of the gate electrode GE is interposed between each semiconductor pattern of the first channel pattern CH1 in the third direction D3. In some cases, each inner electrode of the gate electrode GE is interposed between each semiconductor pattern of the second channel pattern CH2 in the third direction D3.

Referring to FIG. 5D, the gate electrode GE may be disposed on a top surface, a bottom surface, and opposite side surfaces of each of the first, second, and third semiconductor patterns SP1, SP2, and SP3. In an embodiment, the transistor according to the present embodiment may be a three-dimensional field effect transistor (e.g., MBCFET or GAAFET), where the gate electrode GE is disposed three-dimensionally to surround the channel patterns (e.g., the first channel pattern CH1 and the second channel pattern CH2).

On the first active region AR1, an inner spacer might not be formed between the first, second, and third inner electrodes PO1, PO2, and PO3 of the gate electrode GE and the first source/drain pattern SD1. For example, the gate insulating layer GI may be formed around the first, second, and third inner electrodes PO1, PO2, and PO3 of the gate electrode GE. Each of the first, second, and third inner electrodes PO1, PO2, and PO3 of the gate electrode GE may be spaced apart from the first source/drain pattern SD1, with the gate insulating layer GI interposed therebetween. For example, the gate insulating layer GI is disposed between the first inner electrode PO1 of the gate electrode GE and the first source/drain pattern SD1. In some cases, the gate insulating layer GI is thickly formed, where the gate insulating layer GI prevents a leakage current from the gate electrode GE.

Referring to FIGS. 4 and 5A to 5D, a pair of gate spacers GS may be respectively disposed on opposite side surfaces of the outer electrode PO4 of the gate electrode GE. In some cases, the pair of gate spacers GS may be disposed on the gate insulating layer GI that covers the outer electrode PO4 of the gate electrode GE. The gate spacers GS may be extended along the gate electrode GE in the first direction D1. Top surfaces of the gate spacers GS may be coplanar with a top surface of the outer electrode PO4 of the gate electrode GE. In some cases, top surfaces of the gate spacers GS may be disposed at a higher level than a level of the top surface of the outer electrode PO4 of the gate electrode GE. In an embodiment, the gate spacers GS may include SiCN, SiCON, SiN, or a combination thereof. In an embodiment, the gate spacers GS may be a multi-layered structure, and the gate spacers GS include two or more of SiCN, SiCON, and SiN.

Referring to FIGS. 4 and 5A to 5D, a gate capping pattern GP may be disposed on the gate electrode GE (or the outer electrode PO4 of the gate electrode GE). The gate capping pattern GP may be extended along the gate electrode GE in the first direction D1. The gate capping pattern GP may include a material having an etch selectivity with respect to first interlayer insulating layer 110 and second interlayer insulating layer 120. For example, the gate capping pattern GP may include SiON, SiCN, SiCON, SiN, or a combination thereof.

The gate insulating layer GI may be interposed between the gate electrode GE and the first channel pattern CH1 and between the gate electrode GE and the second channel pattern CH2. The gate insulating layer GI may cover top, bottom, and opposite side surfaces of each of the first, second, and third semiconductor patterns SP1, SP2, and SP3. The gate insulating layer GI may cover the top surface of the device isolation layer ST. The gate insulating layer GI may be disposed below the gate electrode GE.

In an embodiment, the gate insulating layer GI may include a silicon oxide layer, a silicon oxynitride layer, and/or a high-k dielectric layer. For example, the gate insulating layer GI may have a structure, in which a silicon oxide layer and a high-k dielectric layer are stacked. The high-k dielectric layer may one or more high-k dielectric materials whose dielectric constants are higher than that of silicon oxide. For example, the high-k dielectric material may include one or more of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

In an embodiment, the semiconductor device may include a negative capacitance (NC) FET using a negative capacitor. For example, the gate insulating layer GI may include a ferroelectric layer exhibiting a ferroelectric property and a paraelectric layer exhibiting a paraelectric property.

The ferroelectric layer may have a negative capacitance, and the paraelectric layer may have a positive capacitance. For example, when two or more capacitors are connected in series and each capacitor has a positive capacitance, a total capacitance may be reduced to a value that is less than a capacitance of each of the capacitors. By contrast, when at least one of serially-connected capacitors has a negative capacitance, a total capacitance of the serially-connected capacitors may have a positive value and may be greater than an absolute value of each capacitance.

For example, when a ferroelectric layer having a negative capacitance and a paraelectric layer having a positive capacitance are connected in series, a total capacitance of the serially-connected ferroelectric and paraelectric layers may be increased. Accordingly, a transistor including the ferroelectric layer may have a subthreshold swing (SS) based on the increase of the total capacitance, where the subthreshold swing (SS) is less than 60 m V/decade at the room temperature.

The ferroelectric layer may have the ferroelectric property. The ferroelectric layer may include one or more of hafnium oxide, hafnium zirconium oxide, barium strontium titanium oxide, barium titanium oxide, and/or lead zirconium titanium oxide. In some cases, for example, the hafnium zirconium oxide may be hafnium oxide doped with zirconium (Zr). Alternatively, the hafnium zirconium oxide may be a compound including hafnium (Hf), zirconium (Zr), and/or oxygen (O).

In some cases, the ferroelectric layer may include dopants. For example, the dopants may include one or more of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The kind of the dopants in the ferroelectric layer may vary based on a ferroelectric material included in the ferroelectric layer.

In some cases, for example, when the ferroelectric layer includes hafnium oxide, the dopants in the ferroelectric layer may include one or more of gadolinium (Gd), silicon (Si), zirconium (Zr), aluminum (Al), and/or yttrium (Y).

In some cases, for example, when the dopants are aluminum (Al), a content of aluminum in the ferroelectric layer may range from 3 at % to 8 at % (atomic percentage). For example, the content of the dopants (e.g., aluminum atoms) may be a ratio of the number of aluminum atoms to the number of hafnium and aluminum atoms.

In some cases, for example, when the dopants are silicon (Si), a content of silicon in the ferroelectric layer may range from 2 at % to 10 at %. In some cases, for example, when the dopants are yttrium (Y), a content of yttrium in the ferroelectric layer may range from 2 at % to 10 at %. In some cases, for example, when the dopants are gadolinium (Gd), a content of gadolinium in the ferroelectric layer may range from 1 at % to 7 at %. In some cases, for example, when the dopants are zirconium (Zr), a content of zirconium in the ferroelectric layer may range from 50 at % to 80 at %.

The paraelectric layer may have the paraelectric property. The paraelectric layer may include one or more of silicon oxide and/or high-k metal oxides. The metal oxides, which can be used as the paraelectric layer, may include one or more of hafnium oxide, zirconium oxide, and/or aluminum oxide. However, the present inventive concept is not necessarily limited to these examples described above.

The ferroelectric layer and the paraelectric layer may include the same material. The ferroelectric layer may have the ferroelectric property, but the paraelectric layer might not have the ferroelectric property. For example, when the ferroelectric and paraelectric layers include hafnium oxide, a crystal structure of the hafnium oxide in the ferroelectric layer may be different from a crystal structure of the hafnium oxide in the paraelectric layer.

The ferroelectric layer may exhibit the ferroelectric property when the thickness of the ferroelectric layer is in a certain range. In an embodiment, the ferroelectric layer may have a thickness ranging from 0.5 nm to 10 nm, but the inventive concept is not necessarily limited thereto. Since a critical thickness associated with the occurrence of the ferroelectric property varies depending on the kind of the ferroelectric material, the thickness of the ferroelectric layer may be changed based on the kind of the ferroelectric material.

For example, the gate insulating layer GI may include a single ferroelectric layer. For example, the gate insulating layer GI may include a plurality of ferroelectric layers spaced apart from each other. The gate insulating layer GI may have a multi-layered structure, in which a plurality of ferroelectric layers and a plurality of paraelectric layers are alternately stacked.

Referring to FIGS. 4 and 5A to 5D, the gate electrode GE may include a first metal pattern and a second metal pattern disposed on the first metal pattern. The first metal pattern may be disposed on the gate insulating layer GI and may be adjacent to the first, second, and third semiconductor patterns SP1, SP2, and SP3. The first metal pattern may include a work-function metal, which can be used to adjust a threshold voltage of the transistor. By adjusting a thickness and composition of the first metal pattern, a transistor having a target threshold voltage can be achieved. For example, the first, second, and third inner electrodes PO1, PO2, and PO3 of the gate electrode GE may be include the first metal pattern or the work-function metal.

The first metal pattern may include a metal nitride layer. For example, the first metal pattern may include one or more of titanium (Ti), tantalum (Ta), aluminum (Al), tungsten (W) and molybdenum (Mo), and/or nitrogen (N). In an embodiment, the first metal pattern may include carbon (C). In some cases, the first metal pattern may include a plurality of work function metal layers that are stacked.

The second metal pattern may include a metallic material whose resistance is lower than the resistance of the first metal pattern. For example, the second metal pattern may include one or more of tungsten (W), aluminum (Al), titanium (Ti), and tantalum (Ta). The outer electrode PO4 of the gate electrode GE may include the first metal pattern and the second metal pattern disposed on the first metal pattern.

A first interlayer insulating layer 110 may be disposed on the substrate 105. In some cases, for example, the first interlayer insulating layer 110 may cover the gate spacers GS and the first and second source/drain patterns SD1 and SD2. For example, the first interlayer insulating layer 110 may cover the etch stop layer ESL on the first and second source/drain patterns SD1 and SD2. A top surface of the first interlayer insulating layer 110 may be substantially coplanar with the top surface of the gate capping pattern GP and the top surface of the gate spacer GS. A second interlayer insulating layer 120 may be disposed on the first interlayer insulating layer 110 to cover the gate capping pattern GP and the gate spacer GS. A third interlayer insulating layer 130 may be disposed on the second interlayer insulating layer 120. A fourth interlayer insulating layer 140 may be disposed on the third interlayer insulating layer 130. In an embodiment, one or more of the first, second, third, and fourth interlayer insulating layers 110, 120, 130, and 140 may include a silicon oxide layer.

As shown in FIG. 4, the single height cell SHC may have a first border BD1 and a second border BD2, which are opposite to each other in the second direction D2. The first and second borders BD1 and BD2 are parallel and may be extended in the first direction D1. The single height cell SHC may have a third border BD3 and a fourth border BD4, which are opposite to each other in the first direction D1. The third and fourth borders BD3 and BD4 are parallel and may be extended in the second direction D2. In some cases, the first border BD1 intersects the third border BD3 and the fourth border BD4. In some cases, the second border BD2 intersects the third border BD3 and the fourth border BD4.

A pair of division structures DB, which are opposite to each other in the second direction D2, may be provided at both sides of the single height cell SHC. For example, the pair of the division structures DB may be respectively disposed on the first and second borders BD1 and BD2 of the single height cell SHC. The division structure DB may be extended in the first direction D1 and parallel to the gate electrodes GE. A pitch between the division structure DB and the gate electrode GE adjacent thereto may be equal to the first pitch.

The division structure DB may penetrate the first and second interlayer insulating layers 110 and 120 and may be extended into the first and second insulating patterns AP1 and AP2. The division structure DB may penetrate an upper portion of each of the first and second insulating patterns AP1 and AP2. In some cases, for example, a level of a bottom surface the division structure DB may be lower than a bottom surface of the first inner electrode PO1 of the gate electrode GE. In some cases, an upper surface of the division structure DB may be coplanar with the upper surface of the second interlayer insulating layer 120. The division structure DB may electrically separate an active region of the single height cell SHC from an active region of a neighboring cell.

In some embodiments, active contacts AC may be disposed on substrate 105. For example, active contacts AC may penetrate the first and second interlayer insulating layers 110 and 120. In some cases, an upper surface of the active contacts may be substantially coplanar with the upper surface of the second interlayer insulating layer 120. In some cases, a bottom surface of the active contacts AC may be lower than the outer electrode PO4 of the gate electrode GE. In one aspect, active contacts AC are electrically connected to the first and second source/drain patterns SD1 and SD2, respectively. A pair of the active contacts AC may be respectively disposed at both sides of the gate electrode GE. When viewed in a plan view, the active contact AC may be a bar-shaped pattern extended along the first direction D1. The active contacts AC may be arranged in the second direction D2.

In some cases, the active contact AC may be a self-aligned contact. For example, the active contact AC may be formed by a self-alignment process using the gate capping pattern GP and the gate spacer GS. For example, the active contact AC may cover at least a portion of the side surface of the gate spacer GS. In some cases, the active contact AC may cover a portion of the top surface of the gate capping pattern GP.

Metal-semiconductor compound layers SC (e.g., silicide layers) may be interposed between the active contact AC and the first source/drain pattern SD1. The metal-semiconductor compound layers SC may be interposed between the active contact AC and the second source/drain pattern SD2. The active contact AC may be electrically connected to the source/drain pattern SD1 or SD2 through the metal-semiconductor compound layer SC. For example, the metal-semiconductor compound layer SC may one or more of titanium silicide, tantalum silicide, tungsten silicide, nickel silicide, and/or cobalt silicide.

In some embodiments, gate contacts GC may be disposed on substrate 105. For example, gate contacts GC may penetrate the second interlayer insulating layer 120 and the gate capping pattern GP and gate contacts GC may be electrically connected to the gate electrodes GE, respectively. In some cases, an upper surface of the gate contacts GC may be coplanar with an upper surface of the second interlayer insulating layer 120. When viewed in a plan view, the gate contacts GC may be disposed to be respectively overlapped with the first and second active regions AR1 and AR2. For example, the gate contact GC may be disposed on the second insulating pattern AP2 (e.g., see FIG. 5B).

In an embodiment, referring to FIG. 5B, an upper portion of the active contact AC adjacent to the gate contact GC may be filled with an upper insulating pattern UIP. A bottom surface of the upper insulating pattern UIP may be lower than a bottom surface of the gate contact GC. For example, a top surface of the active contact AC adjacent to the gate contact GC may be formed at a level, which is higher than the bottom surface of the gate contact GC, by the upper insulating pattern UIP. Accordingly, the gate contact GC and the active contact AC, which are adjacent to each other, might not be in contact with each other and thereby preventing a short circuit issue from occurring therebetween.

Each of the active and gate contacts AC and GC may include a conductive pattern FM and a barrier pattern BM surrounding the conductive pattern FM. For example, the conductive pattern FM may include one or more metallic materials (e.g., aluminum, copper, tungsten, molybdenum, and/or cobalt). The barrier pattern BM may be disposed to cover side surfaces and a bottom surface of the conductive pattern FM. In an embodiment, the barrier pattern BM may include a metal layer and a metal nitride layer. The metal layer may include one or more of titanium, tantalum, tungsten, nickel, cobalt, and/or platinum. The metal nitride layer may one or more of titanium nitride (TiN), tantalum nitride (TaN), tungsten nitride (WN), nickel nitride (NiN), cobalt nitride (CoN), and/or platinum nitride (PtN).

A first metal layer M1 may be disposed in the third interlayer insulating layer 130. For example, the first metal layer M1 may include the first power line M1_R1, the second power line M1_R2, and first interconnection lines M1_I. Each of the first and second power lines M1_R1 and M1_R2 and the first interconnection lines M1_I of the first metal layer M1 may be extended in the second direction D2 and parallel to each other.

For example, the first and second power lines M1_R1 and M1_R2 may be respectively disposed on the third and fourth borders BD3 and BD4 of the single height cell SHC. The first power line M1_R1 may be extended along the third border BD3 in the second direction D2. The second power line M1_R2 may be extended along the fourth border BD4 in the second direction D2.

The first interconnection lines M1_I of the first metal layer M1 may be disposed between the first and second power lines M1_R1 and M1_R2. The first interconnection lines M1_I of the first metal layer M1 may be arranged at a second pitch in the first direction D1. The second pitch may be smaller than the first pitch. A line width of each of the first interconnection lines M1_I may be smaller than a line width of each of the first and second power lines M1_R1 and M1_R2.

The first metal layer M1 may include first vias VI1. The first vias VI1 may be respectively disposed below the first and second power lines M1_R1 and M1_R2 and the first interconnection lines M1_I of the first metal layer M1. The active contact AC and the interconnection line of the first metal layer M1 may be electrically connected to each other through the first via VI1. The gate contact GC and the interconnection line of the first metal layer M1 may be electrically connected to each other through the first via VI1.

The interconnection line of the first metal layer M1 and the first via VI1 thereunder may be formed by separate processes. For example, the interconnection line and the first via VI1 of the first metal layer M1 may be independently formed by respective single damascene processes. The semiconductor device according to the present embodiment may be fabricated using a sub-20 nm process.

A second metal layer M2 may be disposed in the fourth interlayer insulating layer 140. In some cases, the second metal layer M2 may be disposed on the first metal layer M1. The second metal layer M2 may include a plurality of second interconnection lines M2_I. Each of the second interconnection lines M2_I of the second metal layer M2 may be a line-shaped or bar-shaped pattern that extends in the first direction D1. For example, the second interconnection lines M2_I may be extended in the first direction D1 and parallel to each other.

The second metal layer M2 may include second vias VI2, which are respectively disposed below the second interconnection lines M2_I. The interconnection lines of the first and second metal layers M1 and M2 may be electrically connected to each other through the second via VI2. The interconnection line of the second metal layer M2 and the second via VI2 thereunder may be formed together by a dual damascene process.

The interconnection lines of the first metal layer M1 may include a conductive material that is the same as or different from the interconnection lines of the second metal layer M2. For example, the interconnection lines of the first and second metal layers M1 and M2 may include one or more of metallic materials (e.g., aluminum, copper, tungsten, ruthenium, molybdenum, and/or cobalt). In some cases, a plurality of metal layers (e.g., M3, M4, M5, and so forth) may be additionally stacked on the fourth interlayer insulating layer 140. Each of the stacked metal layers may include interconnection lines, which are used as routing paths between cells.

Referring back to FIGS. 4, 5A, 5B, and 5C, the backside active contact BAC may be disposed in the substrate 105. For example, the backside active contact BAC may be formed to penetrate the first and second insulating patterns AP1 and AP2 and the lower insulating patterns BDP1 and BDP2. The backside active contact BAC may be electrically connected to the first and second source/drain patterns SD1 and SD2. When viewed in a plan view, the backside active contact BAC may be a bar-shaped pattern that extends in the first direction D1. Each of the backside active contacts BAC may be arranged and spaced apart in the second direction D2. In some cases, an upper surface of the backside active contact BAC is at a higher level than the bottom surface of the division structures DB.

The backside active contact BAC may be a self-aligned contact, which is formed through a backside surface of the substrate 105. For example, the backside active contact BAC may be formed in a self-aligned manner, using the lower insulating patterns BDP1 and BDP2.

The backside active contact BAC may be inserted into the first and second source/drain patterns SD1 and SD2 through a recess bottom surface of each of the first and second source/drain patterns SD1 and SD2. In an embodiment, a top surface of the backside active contact BAC may be in contact with a bottom surface of each of the first and second source/drain patterns SD1 and SD2. A width of the backside active contact BAC measured in the second direction D2 may increase as a distance to a lower power line VPR decreases. In some cases, the lower insulating patterns BDP1 and BDP2 and the first and second source/drain patterns SD1 and SD2 are in contact with a portion of the side surfaces of the backside active contact BAC.

Backside silicide patterns BSC may be respectively interposed between the backside active contact BAC and the first source/drain pattern SD1 and between the backside active contact BAC and the second source/drain pattern SD2. The backside active contact BAC may be electrically connected to the first and second source/drain patterns SD1 and SD2 through the backside silicide pattern BSC. For example, the backside silicide pattern BSC is disposed between the first source/drain pattern SD1 and the backside active contact BAC. For example, the backside silicide pattern BSC is disposed between the second source/drain pattern SD2 and the backside active contact BAC. The backside silicide pattern BSC may include the same material as the metal-semiconductor compound layer SC described above. For example, the backside silicide pattern BSC may include one or more of titanium silicide, tantalum silicide, tungsten silicide, nickel silicide, and/or cobalt silicide.

The backside active contact BAC may include the conductive pattern FM and the barrier pattern BM surrounding the conductive pattern FM. For example, the conductive pattern FM may include one or more of metallic materials (e.g., aluminum, copper, tungsten, molybdenum, and/or cobalt). The barrier pattern BM may cover side surfaces and top surface of the conductive pattern FM. In an embodiment, the barrier pattern BM may include a metal layer and a metal nitride layer. The metal layer may include one or more of titanium, tantalum, tungsten, nickel, cobalt, and/or platinum. The metal nitride layer may include one or more of titanium nitride (TiN), tantalum nitride (TaN), tungsten nitride (WN), nickel nitride (NiN), cobalt nitride (CoN), and/or platinum nitride (PtN).

The barrier pattern BM of the backside active contact BAC may cover the side surfaces and top surface of the conductive pattern FM of the backside active contact BAC. In an embodiment, the barrier pattern BM may be continuously extended to cover side surfaces and the top surface of the conductive pattern FM.

Referring to FIGS. 4 and 5A to 5D, lower power lines VPR may be disposed in a lower portion of the substrate 105. For example, a bottom surface of the lower power lines VPR may be coplanar with the bottom surface of the substrate 105. When viewed in a plan view, the lower power lines VPR may be extended in the second direction D2 to be parallel to each other in the first direction D1. In an embodiment, each of the lower power lines VPR may be vertically overlapped with each of the first and second active regions AR1 and AR2. The lower power line VPR may be electrically connected to each of the first and second source/drain patterns SD1 and SD2 through the backside active contact BAC.

The lower power line VPR may be formed using a single damascene process. The semiconductor device according to the present embodiment may be fabricated using a sub-20 nm process. The lower power line VPR may include one or more of copper, molybdenum, tungsten, and/or ruthenium.

A power delivery network layer PDN may be disposed under the substrate 105. For example, the power delivery network layer PDN may be disposed on bottom surfaces of the substrate 105 and the lower power line VPR. The power delivery network layer PDN may include a plurality of lower metal lines, which are electrically connected to the lower power line VPR. In an embodiment, the power delivery network layer PDN may include an interconnection network, which is used to apply a source voltage or a drain voltage.

In the semiconductor device according to an embodiment of the present inventive concept, the backside active contact BAC may penetrate the backside surface of the substrate 105 and may be connected the source/drain pattern SD1 or SD2. Accordingly, a back-end-of-line (BEOL) process of forming a metal line on a frontside surface of the substrate 105 may be simplified. For example, a technical difficulty in a metal patterning process of forming an interconnection pattern may be reduced.

In the semiconductor device according to an embodiment of the inventive concept, by lowering a pattern density (i.e., a metal route density) of the first and second metal layers M1 and M2 disposed on the frontside surface of the substrate 105, a signal transferring speed in a process of transmitting an electrical signal to a transistor may be increased. In some cases, a coupling phenomenon may be prevented, where the coupling phenomenon may occur when a gate contact GC and an active contact AC are adjacent to each other in a middle-end-of-line (MOL) process. Accordingly, the electrical and reliability characteristics of the semiconductor device is improved.

In some cases, when the active contact AC and the backside active contact BAC are formed to have the aforementioned structure, the electric characteristics and reliability of the semiconductor device is improved. In some cases, the efficiency in the fabrication process is improved.

FIG. 6A is an enlarged cross-sectional view illustrating an example of a portion ‘M’ of FIG. 5A, and FIGS. 6B and 6C are graphs showing a concentration distribution based on a width or height of a source/drain pattern. Hereinafter, the first source/drain pattern SD1 and the lower insulating patterns BDP1 and BDP2 is described with reference to FIGS. 6A to 6C. A pair of the first source/drain patterns SD1 may be connected to the first, second, and third semiconductor patterns SP1, SP2, and SP3 of the first channel pattern CH1. The paired first source/drain patterns SD1 may include a first sub-source/drain pattern SD1_1 and a second sub-source/drain pattern SD1_2. The first and second sub-source/drain patterns SD1_1 and SD1_2 may have the same conductivity type. For example, the first and second sub-source/drain patterns SD1_1 and SD1_2 may be doped in-situ with n-type impurities (e.g., phosphorus (P), arsenic (As), or antimony (Sb)).

The etch stop layer ESL may be disposed on the first sub-source/drain pattern SD1_1. The first lower insulating pattern BDP1 may be disposed below the first sub-source/drain pattern SD1_1. For example, the first sub-source/drain pattern SD1_1 may be disposed between the etch stop layer ESL and the first lower insulating pattern BDP1. The active contact AC may penetrate the first interlayer insulating layer 110 and the etch stop layer ESL and may be in contact with the first sub-source/drain pattern SD1_1. For example, the active contact AC on the first sub-source/drain pattern SD1_1 may be a pattern formed on the frontside surface of the substrate 105. In some cases, a bottom surface of the active contact AC may be at a lower level than a top surface of the first sub-source/drain pattern SD1_1.

The metal-semiconductor compound layer SC may be interposed between the active contact AC and the first sub-source/drain pattern SD1_1. For example, the metal-semiconductor compound layer SC may be disposed between barrier pattern BM of the active contact AC and the first sub-source/drain pattern SD1_1. The active contact AC may be electrically connected to the first sub-source/drain pattern SD1_1 through the metal-semiconductor compound layer SC.

The etch stop layer ESL may be disposed on the second sub-source/drain pattern SD1_2. The second lower insulating pattern BDP2 may be disposed below the second sub-source/drain pattern SD1_2. The backside active contact BAC may penetrate the substrate 105 and the second lower insulating pattern BDP2 and may be in contact with the second sub-source/drain pattern SD1_2. In some cases, a portion of side surfaces of backside active contact BAC may be in contact with the second sub-source/drain pattern SD1_2. For example, the backside active contact BAC below the second sub-source/drain pattern SD1_2 may be a pattern formed on the backside surface of the substrate 105.

The backside silicide pattern BSC may be interposed between the backside active contact BAC and the second sub-source/drain pattern SD1_2. The backside active contact BAC may be electrically connected to the second sub-source/drain pattern SD1_2 through the backside silicide pattern BSC. The backside silicide pattern BSC may include the same material as the metal-semiconductor compound layer SC.

The first lower insulating pattern BDP1 may be extended from a bottom surface of the first sub-source/drain pattern SD1_1 to a side surface of the first inner electrode PO1. For example, the first lower insulating pattern BDP1 may be extended from a bottom surface of a recess region, in which the first sub-source/drain pattern SD1_1 is formed, to the side surface of the first inner electrode PO1. The second lower insulating pattern BDP2 may be extended from a side surface of the backside active contact BAC to a side surface of the first inner electrode PO1. In some cases, the first lower insulating pattern BDP1 may have a shape that corresponds to a shape of the bottom surface of the first sub-source/drain pattern SD1_1. In some cases, the second lower insulating pattern BDP2 may have a shape that corresponds to a shape of the bottom surface of the second sub-source/drain pattern SD1_2.

A thickness of the first lower insulating pattern BDP1 may decrease as a distance from the bottom surface of the first sub-source/drain pattern SD1_1 increases in a direction toward the side surface of the first inner electrode PO1. A thickness of the second lower insulating pattern BDP2 may decrease as a distance from a side surface of the backside active contact BAC increases in a direction toward a side surface of the first inner electrode PO1. In an embodiment, each of the first and second lower insulating patterns BDP1 and BDP2 may be formed to have a uniform thickness.

The uppermost surface of each of the first and second lower insulating patterns BDP1 and BDP2 may be disposed at the same level as a bottom surface of the first semiconductor pattern SP1. Alternatively, the uppermost surface of each of the first and second lower insulating patterns BDP1 and BDP2 may be located at a level lower than the bottom surface of the first semiconductor pattern SP1.

The first and second lower insulating patterns BDP1 and BDP2 may include one or more of silicon-based insulating materials. For example, the first and second lower insulating patterns BDP1 and BDP2 may include SiNₓ, SiOC, SiOCN, SiON, SiO, SiBCN, SiBC, or any combinations thereof.

The first source/drain patterns SD1, which includes the first and second sub-source/drain patterns SD1_1 and SD1_2, may include a buffer layer BFL, a barrier layer DBL on the buffer layer BFL, and a doping layer DPL filling a space in the barrier layers DBL. For example, the buffer layer BFL may be disposed on the outer side surface of the barrier layers DBL. For example, the barrier layers DBL may be disposed on an outer side surface of the doping layer DPL. A volume of the doping layer DPL may be larger than a volume of the buffer layer BFL and a volume of the barrier layer DBL. The volume of the buffer layer BFL may be larger than the volume of the barrier layer DBL.

The buffer layer BFL may be disposed on side surfaces of first, second, and third inner electrodes PO1, PO2, and PO3 and side surfaces of first, second, and third semiconductor patterns SP1, SP2, and SP3. A horizontal distance of the buffer layer BFL on side surfaces of the first, second, and third inner electrodes PO1, PO2, and PO3 may be larger than a horizontal distance of the buffer layer BFL on side surfaces of the first, second, and third semiconductor patterns SP1, SP2, and SP3. For example, the buffer layer BFL may have a wavy shape. The buffer layer BFL may include undoped silicon, silicon-germanium (SiGe), or silicon carbide (SiC).

As shown in FIG. 6C, the concentration of dopants varies with respect to the buffer layer BFL, the barrier layer DBL, and the doping layer DPL. In some cases, the buffer layer BFL may include a relatively low concentration of dopants. For example, the dopants may be germanium (Ge). The buffer layer BFL may have a first doping concentration C1. The first doping concentration C1 may range from 0 at % to 0.1 at %.

Since the buffer layer BFL includes undoped silicon or a relatively low concentration of dopants, a physical short phenomenon of a transistor or an electrical short phenomenon between the first source/drain pattern SD1 and the gate electrode GE from occurring in the NMOSFET region can be prevented. In addition, the buffer layer BFL may prevent a leakage current (e.g., a gate current leakage) from occurring in the NMOSFET region.

The barrier layer DBL may be disposed on a side surface of the buffer layer BFL. The barrier layer DBL may be formed to have a uniform thickness on the side surface of the buffer layer BFL. In an embodiment, a thickness of the barrier layer DBL measured in the second direction D2 may decrease as a vertical position is changed in the third direction D3 perpendicular to the substrate 105. For example, a thickness of the barrier layer DBL on a side surface of the third semiconductor pattern SP3 may be greater than a thickness of the barrier layer DBL on a side surface of the first or second semiconductor pattern SP1 or SP2. The barrier layer DBL may include silicon-phosphorus (SiP), silicon-arsenic (SiAs), or silicon-antimony (SiSb).

The barrier layer DBL may include a low concentration of dopants. For example, the dopants may be phosphorus (P), arsenic (As), or antimony (Sb). For example, the barrier layer DBL may have a second doping concentration C2. The second doping concentration C2 may range from 0.1 at % to 4 at %.

Since the barrier layer DBL includes a low concentration of dopants, a dopant diffusion in the doping layer DPL can be prevented. For example, the barrier layer DBL may be used to prevent a short channel effect (SCE). For example, the barrier layer DBL may be used to control a dopant diffusion depth (e.g., a junction depth) in the first source/drain pattern SD1.

In some cases, a control layer may be interposed between the buffer layer BFL and the barrier layer DBL. The control layer may include one or more of SiC, SiCAs, or SiCP. A carbon concentration of the control layer may range from 0.1 at % to 0.5 at %. The control layer may prevent the dopant diffusion issue described with reference to the barrier layer DBL.

The doping layer DPL may be interposed between the barrier layers DBL. For example, the doping layer DPL is disposed between a pair of barrier layers DBL. The doping layer DPL may fill an empty space between the barrier layers DBL. For example, the doping layer DPL may be disposed on an inner side surface of the barrier layer DBL.

The doping layer DPL may be vertically overlapped with the backside active contact BAC, the backside silicide pattern BSC, and the etch stop layer ESL. The doping layer DPL may be in direct contact with the backside silicide pattern BSC. For example, the doping layer DPL may be electrically connected to the backside active contact BAC through the backside silicide pattern BSC. The backside silicide pattern BSC might not be vertically overlapped with the buffer layer BFL and the barrier layer DBL. The backside silicide pattern BSC might not be in contact with the buffer layer BFL and the barrier layer DBL.

In some cases, the doping layer DPL may include silicon-phosphorus (SiP) or silicon-arsenic-phosphorus (SiAsP). The doping layer DPL may include a high concentration of dopants. For example, the dopants may be phosphorus (P) or arsenic (As). For example, the doping layer DPL may have a third doping concentration C3. The third doping concentration C3 may range from 4 at % to 12 at %. For example, the doping concentration of the doping layer DPL disposed on the barrier layer DBL may be the smallest (e.g., 4 at %). For example, the doping concentration at a center point of the doping layer DPL may be the largest (e.g., 12 at %).

Since the doping layer DPL includes a high concentration of dopants, a contact resistance between the doping layer DPL and the active contact AC or backside active contact or BAC may be lowered. In addition, the doping layer DPL may lower a resistance between the semiconductor patterns SP1, SP2, and SP3 and the first source/drain pattern SD1.

FIG. 6B is a graph showing a variation of the third doping concentration C3, which is caused by a change in a depth of the doping layer DPL measured in the third direction D3. The third doping concentration C3 of the doping layer DPL may gradually decrease in a direction from the backside active contact BAC toward the etch stop layer ESL. For example, the third doping concentration C3 may be higher in a region adjacent to the first semiconductor pattern SP1 than in a region adjacent to the third semiconductor pattern SP3. In some cases, the third doping concentration C3 may be higher in a region adjacent to the backside silicide pattern BSC than in a region adjacent to the etch stop layer ESL.

FIG. 6C is a graph showing a variation of the doping concentration, which is caused by a change in a width of the first source/drain pattern SD1 measured in the second direction D2. The doping concentration may gradually increase as a distance from a portion of the buffer layer BFL increases in a direction toward a center of the doping layer DPL. The doping concentration may gradually decrease as a distance from the doping layer DPL increases in a direction toward an opposite portion of the buffer layer BFL. The third doping concentration C3 of the doping layer DPL may be higher than the first doping concentration C1 of the buffer layer BFL and the second doping concentration C2 of the barrier layer DBL. The second doping concentration C2 may be higher than the first doping concentration C1.

In some cases, referring to FIG. 6A, voids may be interposed between the first sub-source/drain pattern SD1_1 and the first lower insulating pattern BDP1 and between the second sub-source/drain pattern SD1_2 and the second lower insulating pattern BDP2. For example, voids may be formed in the barrier layer DBL and the doping layer DPL. A total volume of the voids may be 0.001 to 0.02 times a volume of the first sub-source/drain pattern SD1_1. For example, the first and second sub-source/drain patterns SD1_1 and SD1_2 are extended from the side surfaces of the first, second, and third semiconductor patterns SP1, SP2, and SP3. As a result, voids are formed through a selective epitaxial growth (SEG) process.

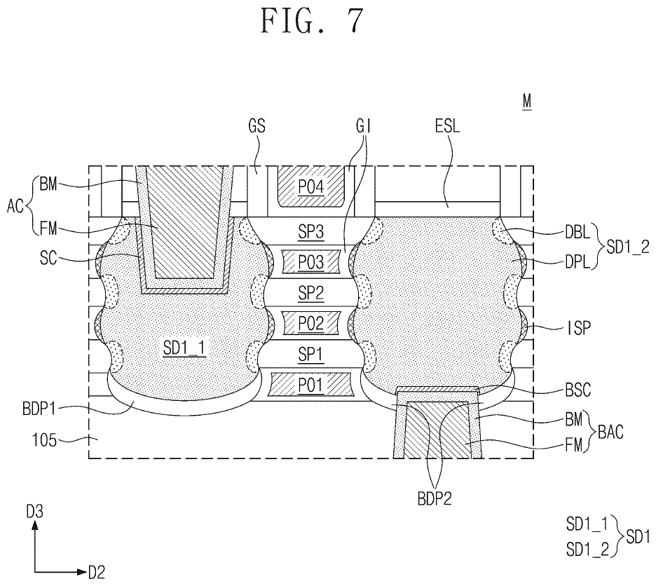

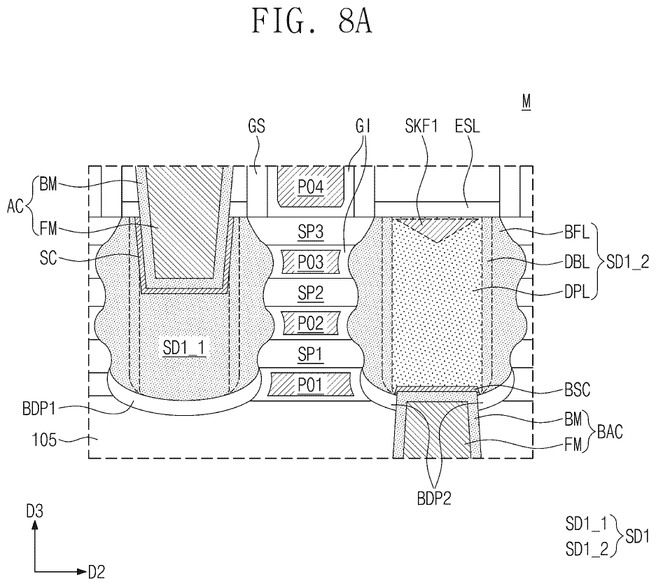

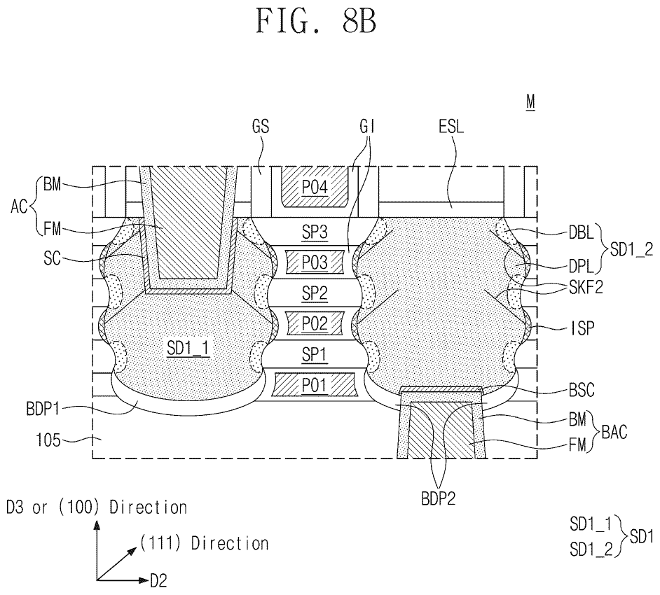

In the following description, an element previously described with reference to FIGS. 4, 5A to 5D, and 6A may be identified by the same reference number without repeating an overlapping description thereof for concise description. FIG. 7 is an enlarged cross-sectional view illustrating an example of the portion ‘M’ of FIG. 5A. FIG. 8A is an enlarged cross-sectional view illustrating the stacking fault of FIG. 6A, and FIG. 8B is an enlarged cross-sectional view illustrating the stacking fault of FIG. 7.

Referring to FIG. 7, inner spacers ISP may be disposed on the first active region AR1 and may be respectively interposed between the second and third inner electrodes PO2 and PO3 of the gate electrode GE and the first source/drain pattern SD1. Each of the second and third inner electrodes PO2 and PO3 of the gate electrode GE may be spaced apart from the first source/drain pattern SD1, with the inner spacer ISP interposed therebetween. For example, each of the second and third inner electrodes PO2 and PO3 are disposed between a pair of inner spacers ISP.

In an embodiment, the inner spacer ISP may be disposed on the side surfaces of the first, second, and third inner electrodes PO1, PO2, and PO3. The inner spacer ISP may be interposed between the first inner electrode PO1 and the first source/drain pattern SD1. However, in an embodiment, the inner spacer ISP may include the same material as the second lower insulating pattern BDP2. For example, the inner spacer ISP on the side surface of the first inner electrode PO1 might not be distinct from the second lower insulating pattern BDP2. In some cases, the gate insulating layer GI may be disposed between each of the inner electrodes and the inner spacers ISP.

The inner spacer ISP may prevent a short circuit from being formed between the gate electrode GE and the first source/drain pattern SD1. For example, the inner spacer ISP may prevent charged carriers from penetrating the thin gate insulating layer GI on the gate electrode GE and from moving between the gate electrode GE and the first source/drain pattern SD1. For example, the inner spacer ISP may prevent a leakage current from the gate electrode GE.

An indent region may be defined between each of the first, second, and third inner electrodes PO1, PO2, and PO3 of the gate electrode GE and the first source/drain pattern SD1. The indent region may be an empty space, which is extended from the first source/drain pattern SD1 to a corresponding one of the first, second, and third inner electrodes PO1, PO2, and PO3. In some cases, each of the first, second, and third inner electrodes PO1, PO2, and PO3 may have a concave side surface based on the indent region.

The inner spacer ISP may be disposed in one of the indent regions adjacent to the second and third inner electrodes PO2 and PO3. In an embodiment, the inner spacer ISP may be disposed to completely fill the indent region. A first surface of the inner spacer ISP may be in direct contact with the gate insulating layer GI. A second surface of the inner spacer ISP, which is opposite to the first surface in the second direction D2, may be in direct contact with the first source/drain pattern SD1.

The inner spacer ISP may include the same material as the first and second lower insulating patterns BDP1 and BDP2. The inner spacer ISP may include a silicon-based insulating material. For example, the inner spacer ISP may include SiNₓ, SiOC, SiOCN, SiON, SiO, SiBCN, SiBC, or any combinations thereof.

The first source/drain patterns SD1, which includes the first and second sub-source/drain patterns SD1_1 and SD1_2, may include the barrier layers DBL and the doping layer DPL disposed on the barrier layers DBL. A volume of the doping layer DPL may be larger than a volume of the barrier layer DBL.

The barrier layers DBL may be respectively disposed on side surfaces of the first, second, and third semiconductor patterns SP1, SP2, and SP3. For example, after the formation of the inner spacers ISP, the barrier layers DBL may be locally formed on the side surfaces of the first, second, and third semiconductor patterns SP1, SP2, and SP3 during a subsequent SEG process of forming the first source/drain pattern SD1. The barrier layer DBL may include silicon-phosphorus (SiP), silicon-arsenic (SiAs), or silicon-antimony (SiSb). The barrier layer DBL may include a low concentration of dopants. For example, the dopants may be phosphorus (P), arsenic (As), or antimony (Sb).

The doping layer DPL may be disposed within the barrier layers DBL. The doping layer DPL may be formed to fill a remaining empty space of the recess region, in which the barrier layers DBL are formed. In the recess region, the doping layer DPL may be formed to surround the inner surface of the barrier layers DBL. The doping layer DPL may include silicon-phosphorus (SiP) or silicon-arsenic-phosphorus (SiAsP). The doping layer DPL may include a high concentration of dopants. For example, a doping concentration of the doping layer DPL may be higher than a doping concentration of the barrier layer DBL.

Referring to FIGS. 8A and 8B, the first source/drain pattern SD1 may have various stacking faults based on the presence or absence of the inner spacer ISP. For example, when the inner spacer ISP is not provided between the first source/drain pattern SD1 and the first, second, and third inner electrodes PO1, PO2, and PO3 of the gate electrode GE, a first stacking fault SKF1 may be formed in an upper portion of the first source/drain pattern SD1, as shown in FIG. 8A.

For example, since the buffer layer BFL, the barrier layer DBL, and the doping layer DPL are formed of silicon-based materials, the first stacking fault SKF1 might not be formed in a lower or side portions of the first source/drain pattern SD1. For example, the first stacking fault SKF1 may be formed in the last stage of a SEG process of forming the doping layer DPL. When viewed in a sectional view, the first stacking fault SKF1 may have a triangular shape.

In some embodiments, when the inner spacer ISP is formed between the first source/drain pattern SD1 and the first, second, and third inner electrodes PO1, PO2, and PO3 of the gate electrode GE, a second stacking fault SKF2 may be formed in the side and upper portions of the first source/drain pattern SD1, as shown in FIG. 8B.

For example, the second stacking fault SKF2 may be formed from the inner spacer ISP, which is adjacent to the barrier layer DBL, during a process of forming the barrier layer DBL and the doping layer DPL. In some cases, the barrier layer DBL and the doping layer DPL are formed of, or include, materials different from the inner spacer ISP. The second stacking fault SKF2 may be extended from the side portion of the first source/drain pattern SD1 to the center portion or may be extended from the side portion of the first source/drain pattern SD1 to the upper portion.

For example, the second stacking fault SKF2 may be formed from an early stage of the SEG process of forming the doping layer DPL. When viewed in a sectional view, the second stacking fault SKF2 may have a line shape that is inclined at an angle. The second stacking fault SKF2 may be extended from the inner spacer ISP in a (111) direction of the substrate 105. When viewed in a sectional view, the (111) direction may not be parallel to both the second and third directions D2 and D3. For example, the second stacking fault SKF2 may be extended from the inner spacer ISP in a (100) direction of the substrate 105.

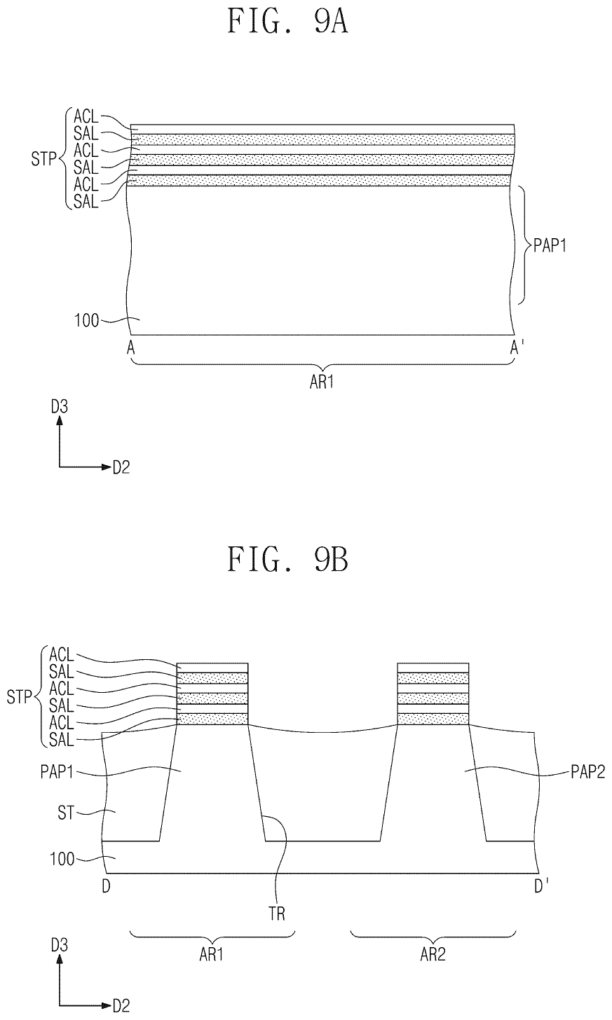

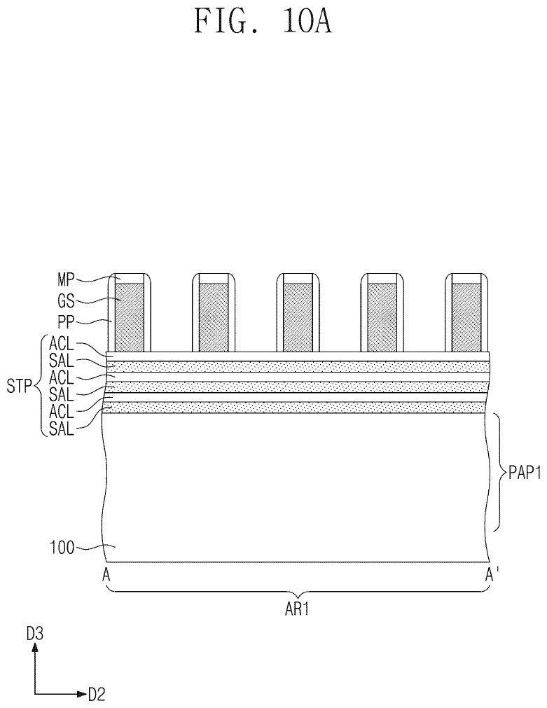

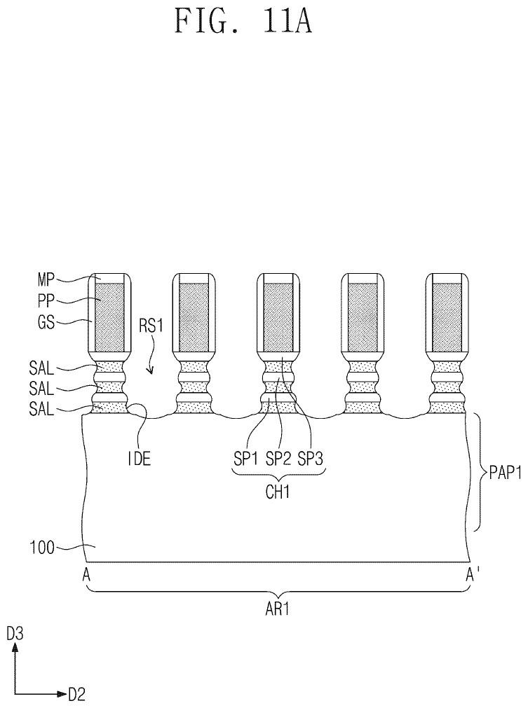

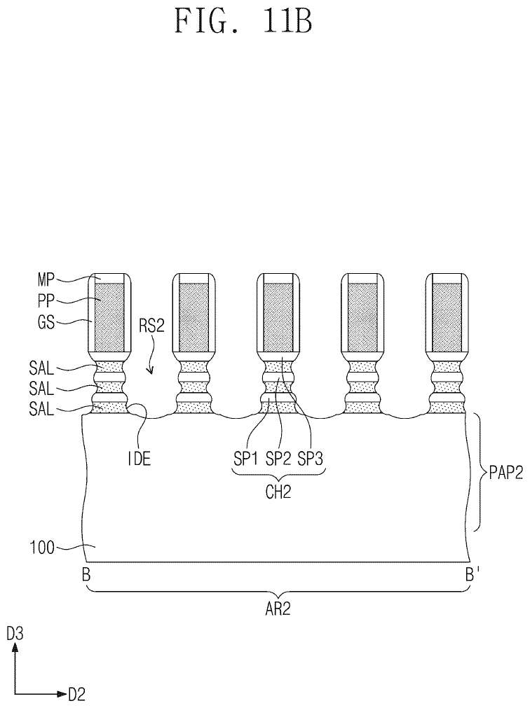

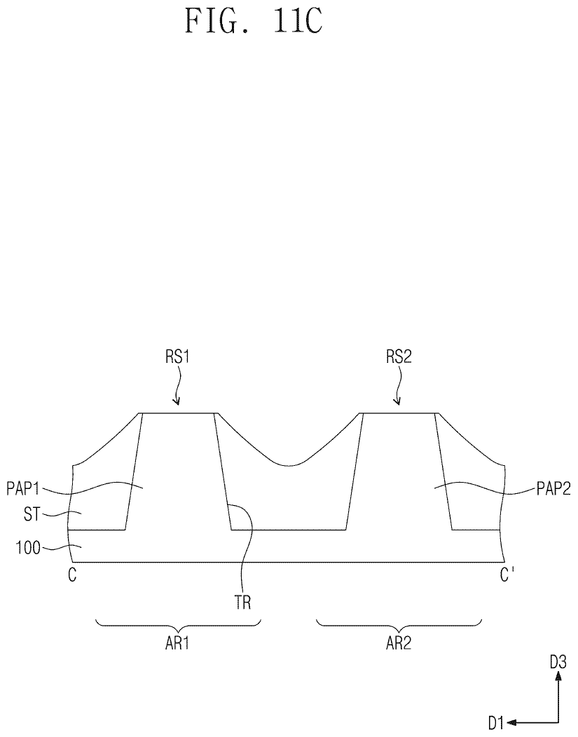

FIGS. 9A to 18C are cross-sectional views illustrating a method of fabricating a semiconductor device, according to an embodiment of present the inventive concept. For example, FIGS. 9A, 10A, 11A, 12A, 13A, 14A, 15A, 16A, 17A, and 18A are cross-sectional views corresponding to the line A-A′ of FIG. 4. FIGS. 11B, 12B, 13B, 14B, 15B, 16B, 17B, and 18B are cross-sectional views corresponding to the line B-B′ of FIG. 4. FIGS. 11C, 12C, 13C, 14C, 15C, 16C, 17C, and 18C are cross-sectional views corresponding to the line C-C′ of FIG. 4. FIGS. 9B, 10B, 13D, 14D, and 15D are cross-sectional views corresponding to the line D-D′ of FIG. 4.

Referring to FIGS. 9A and 9B, the substrate 100 including the first and second active regions AR1 and AR2 may be provided. The substrate 100 may be a semiconductor substrate including silicon, germanium, silicon germanium, a compound semiconductor material, or the like. In an embodiment, the substrate 100 may be a silicon wafer. Active layers ACL and sacrificial layers SAL may be alternately stacked on and disposed on the substrate 100. The active layers ACL may include one of silicon (Si), germanium (Ge), and silicon germanium (SiGe). The sacrificial layers SAL may include one of silicon (Si), germanium (Ge), and silicon germanium (SiGe). In some cases, the active layers ACL and sacrificial layers SAL include different materials.

The sacrificial layer SAL may include a material having an etch selectivity less than an etch selectivity of the active layer ACL. For example, the active layers ACL may include silicon (Si), and the sacrificial layers SAL may include silicon germanium (SiGe). A germanium concentration of each of the sacrificial layers SAL may range from 10 at % to 30 at %.

Mask patterns may be respectively formed on the first and second active regions AR1 and AR2 of the substrate 100. The mask pattern may be a line-shaped or bar-shaped pattern that extends in the second direction D2.

For example, a patterning process using the mask patterns as an etch mask may be performed to form the trench TR that outlines the first and second active patterns PAP1 and PAP2. The first active pattern AP1 may be formed on the first active region AR1. The second active pattern AP2 may be formed on the second active region AR2. Each of the first and second active patterns PAP1 and PAP2 may be a vertically-protruding portion of the substrate 100. In some cases, a length, measured in the second direction, of the trench TR closer toward a bottom surface of the substrate 100 is less than a length, measured in the second direction, of the trench TR away from the bottom surface of the substrate 100.

A stacking pattern STP may be formed on each of the first and second active patterns PAP1 and PAP2. The stacking pattern STP may include the active layers ACL and the sacrificial layers SAL which are alternately stacked. The stacking pattern STP may be formed along with the first and second active patterns PAP1 and PAP2, during the patterning process. In some cases, for example, the sacrificial layer SAL is disposed on and contacts the first and second active patterns PAP1 and PAP2.

The device isolation layer ST may be formed to fill the trench TR or a portion of the trench TR. For example, an insulating layer may be formed on the substrate 100 to cover the first and second active patterns PAP1 and PAP2 and the stacking patterns STP. The device isolation layer ST may be formed by recessing the insulating layer to expose the stacking patterns STP.

The device isolation layer ST may one or more of insulating materials (e.g., silicon oxide). The stacking patterns STP may be disposed at a level higher than the device isolation layer ST and may be exposed to the outside of the device isolation layer ST. For example, the bottom-most sacrificial layer SAL is at a level higher than the device isolation layer ST. For example, the stacking patterns STP may protrude vertically above the device isolation layer ST.

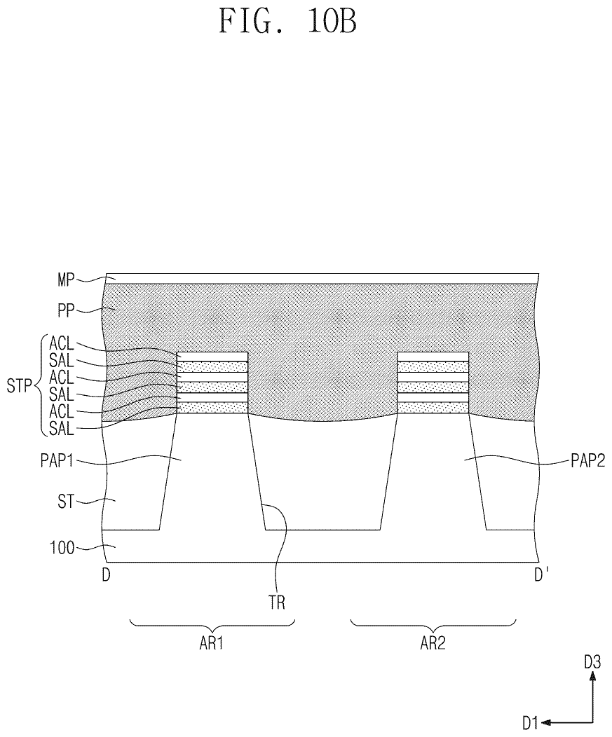

Referring to FIGS. 10A and 10B, sacrificial patterns PP may be formed on the substrate 100 to cover the stacking patterns STP. Each of the sacrificial patterns PP may be a line-shaped or bar-shaped pattern that extends in the first direction D1. The sacrificial patterns PP may be arranged at a first pitch in the second direction D2.

For example, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may include polysilicon.

A pair of the gate spacers GS may be formed on opposite side surfaces of each of the sacrificial patterns PP. The formation of the gate spacers GS may include conformally forming a gate spacer layer on the substrate 100 (or stacking patterns STP) and anisotropically etching the gate spacer layer. In an embodiment, the gate spacer GS may be a multi-layered structure including at least two layers.

Referring to FIGS. 11A to 11C, the first recesses RS1 may be formed in the stacking pattern STP on the first active pattern PAP1. The second recesses RS2 may be formed in the stacking pattern STP on the second active pattern PAP2. During the formation of the first and second recesses RS1 and RS2, the device isolation layer ST may also be recessed at both sides of each of the first and second active patterns PAP1 and PAP2 (e.g., see FIG. 11C).

For example, the first recesses RS1 may be formed by etching the stacking pattern STP, which is formed on the first active pattern PAP1, using the hard mask patterns MP and the gate spacers GS as an etch mask. The first recess RS1 may be formed between a pair of the sacrificial patterns PP. A selective etching process may be performed on the sacrificial layers SAL exposed by the first recess RS1 to form indent regions IDE on the first active pattern PAP1 and on the stacking pattern STP. As a result, an inner side surface of the first recess RS1 may have a wavy profile based on the indent regions IDE.

The first, second, and third semiconductor patterns SP1, SP2, and SP3, which are sequentially stacked between adjacent ones of the first recesses RS1, may be respectively formed from the active layers ACL. In some cases, the first channel pattern CH1 includes the first, second, and third semiconductor patterns SP1, SP2, and SP3 that are vertically stacked on each other and spaced apart by the sacrificial layers SAL.

Referring to FIGS. 11A to 11C, the second recesses RS2 in the stacking pattern STP on the second active pattern PAP2 may be formed by a method similar to that of the first recesses RS1. A selective etching process may be performed on the sacrificial layers SAL, which are exposed by the second recess RS2, to form the indent regions IDE on the second active pattern PAP2. Accordingly, the second recess RS2 may have a wavy inner side surface based on the indent regions IDE. In some cases, the second channel pattern CH2 includes the first, second, and third semiconductor patterns SP1, SP2, and SP3 vertically stacked on each other and spaced apart by the sacrificial layers SAL.

Referring to FIG. 7, the inner spacer ISP may be formed on the indent regions IDE. For example, the formation of the inner spacer ISP may include exposing the sacrificial layers SAL through the first recess RS1 and performing a selective etching process on the exposed sacrificial layers SAL. The selective etching process may include a wet etching process of selectively removing silicon-germanium. As a result of the etching process, the indent regions on each of the sacrificial layers SAL may be formed to have deeper concavities. An insulating layer may be formed in the first recess RS1 to fill the indent regions with the deeper concavities. A wet etching process may be performed on the insulating layer to expose side surfaces of the first, second, and third semiconductor patterns SP1, SP2, and SP3. Thus, the inner spacer ISP may be formed.

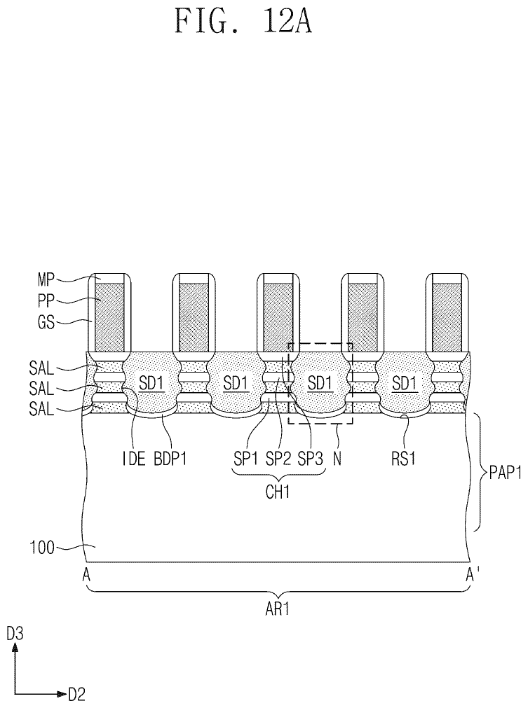

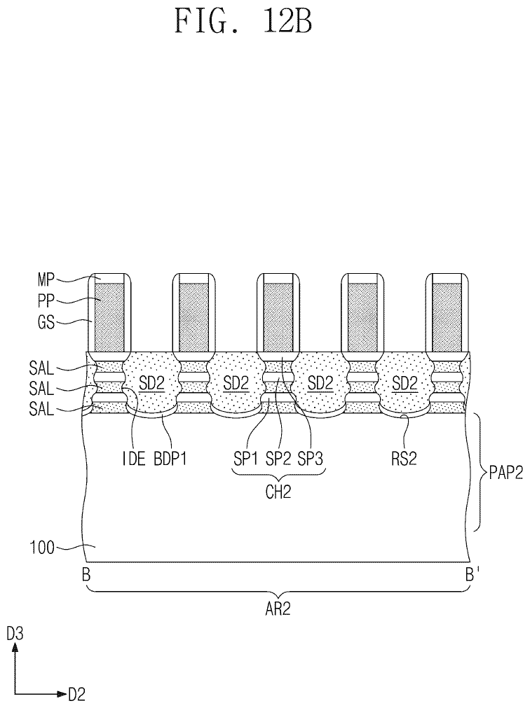

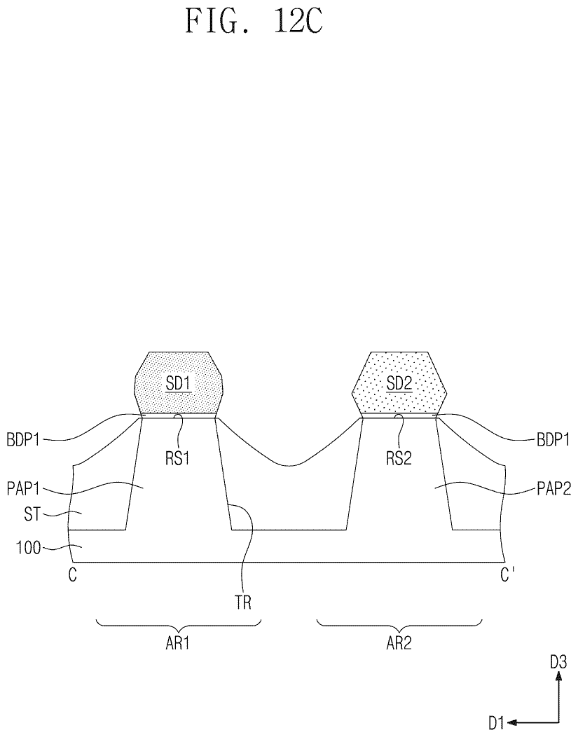

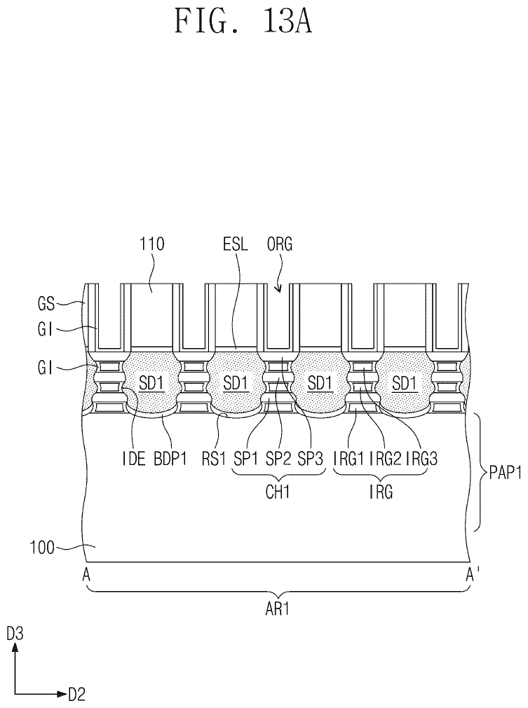

Referring to FIGS. 12A to 12C, the first lower insulating pattern BDP1 and the first source/drain patterns SD1 may be formed in the first recesses RS1, respectively. The first lower insulating pattern BDP1 may be formed on a bottom surface of the first recess RS1, and the first source/drain pattern SD1 may be formed on the first lower insulating pattern BDP1. In some cases, the first source/drain pattern SD1 has a shape of the first recess RS1. For example, the first source/drain pattern SD1 and the first lower insulating pattern BDP1 fills the spaces in the first recesses RS1. In some cases, a top surface of the first source/drain pattern SD1 is coplanar with the top surface of the third semiconductor pattern SP3. The first lower insulating pattern BDP1 and the second source/drain patterns SD2 may be formed in the second recesses RS2, respectively. The first lower insulating pattern BDP1 may be formed on a bottom surface of the second recess RS2, and the second source/drain pattern SD2 may be formed on the first lower insulating pattern BDP1. In some cases, the second source/drain pattern SD2 has a shape of the second recess RS2. For example, the second source/drain pattern SD2 and the first lower insulating pattern BDP1 fills the spaces in the second recesses RS2. In some cases, a top surface of the second source/drain pattern SD2 is coplanar with the top surface of the third semiconductor pattern SP3

For example, a SEG process, in which an inner surface of the first recess RS1 is used as a seed layer, may be performed to form an epitaxial layer filling the first recess RS1. The epitaxial layer may be grown using the first, second, and third semiconductor patterns SP1, SP2, and SP3 and the substrate 100, which are exposed by the first recess RS1, as the seed layer. In an embodiment, the SEG process may include a chemical vapor deposition (CVD) process or a molecular beam epitaxy (MBE) process.

In an embodiment, the first source/drain pattern SD1 may include the same semiconductor material (e.g., Si) as the substrate 100. During the formation of the first source/drain pattern SD1, the first source/drain pattern SD1 may be doped in-situ with n-type impurities (e.g., phosphorus, arsenic, or antimony). Alternatively, impurities may be injected into the first source/drain pattern SD1 after the formation of the first source/drain pattern SD1.

For example, the second source/drain pattern SD2 may be formed by a SEG process using an inner surface of the second recess RS2 as a seed layer. In an embodiment, the second source/drain pattern SD2 may include a semiconductor material (e.g., SiGe) whose lattice constant is greater than the lattice constant of a semiconductor material of the substrate 100 or the first source/drain pattern SD1. During the formation of the second source/drain pattern SD2, the second source/drain pattern SD2 may be doped in-situ with p-type impurities (e.g., boron, gallium, or indium). Alternatively, impurities may be injected into the second source/drain pattern SD2 after the formation of the second source/drain pattern SD2.

The first and second source/drain patterns SD1 and SD2 may have top surfaces that are substantially coplanar with the top surface of the third semiconductor pattern SP3. In an embodiment, when the first and second source/drain patterns SD1 and SD2 are over-grown, the top surfaces of the first and second source/drain patterns SD1 and SD2 may be at a level higher than the top surface of the third semiconductor pattern SP3. In an embodiment, when the first and second source/drain patterns SD1 and SD2 are under-grown, the top surfaces of the first and second source/drain patterns SD1 and SD2 may be located at a level lower than the top surface of the third semiconductor pattern SP3. In an embodiment, a vertical distance from the top surface of the third semiconductor pattern SP3 to a top surface of each of the first and second source/drain patterns SD1 and SD2 may range from −2 nm to 5 nm.

Further detail on the formation of the first lower insulating patterns BDP1 and the first source/drain pattern SD1 is described with reference to FIGS. 19 to 24. FIGS. 19 to 24 are enlarged cross-sectional views illustrating a method of forming the first source/drain pattern SD1 in a portion ‘N’ of FIG. 12A.

Referring to FIG. 19, a preliminary insulating layer PBDL may be formed to cover the bottom surface and side surfaces of the first recess RS1. Due to the wavy inner side surface of the first recess RS1, an outer side surface of the preliminary insulating layer PBDL may have a wavy profile. In some cases, an inner side surface of the preliminary insulating layer PBDL may have a curved profile. The preliminary insulating layer PBDL may be formed by performing a chemical vapor deposition (CVD) process. The preliminary insulating layer PBDL may include SiNₓ, SiOC, SiOCN, SiON, SiO, SiBCN, SiBC, or any combinations thereof.

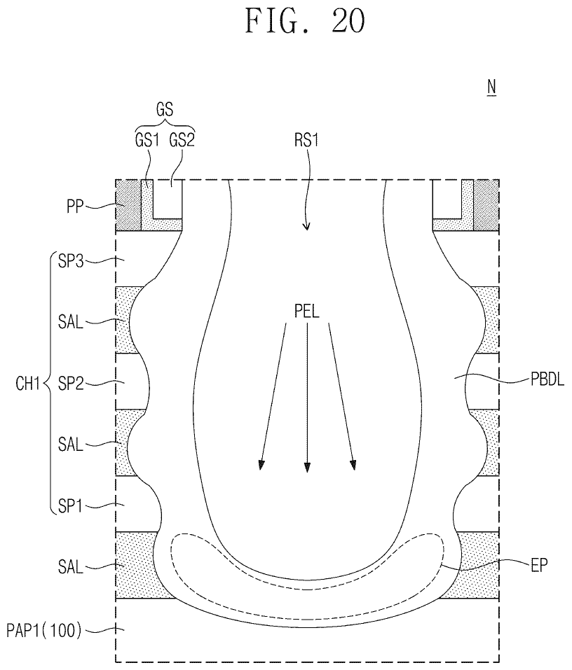

Referring to FIG. 20, the chemical vapor deposition (CVD) process may be a plasma-enhanced CVD (PE-CVD) process or a high density plasma (HDP) process. By using the plasma, the hardness or density of a portion of the preliminary insulating layer PBDL may be increased. For example, the reaction energy of the plasma may be used to increase the density of the preliminary insulating layer PBDL, and thus, the preliminary insulating layer PBDL may have a reduced reactivity in an etching process.

Based on a direction PEL of the plasma, the hardness or density of a lower portion EP of the preliminary insulating layer PBDL may be selectively increased. For example, the lower portion EP of the preliminary insulating layer PBDL may have a density higher than a side portion of the preliminary insulating layer PBDL. The direction PEL of the plasma may be based on a magnitude or phase of an applied RF power. Accordingly, by adjusting the applied RF power, the density of the lower portion EP of the preliminary insulating layer PBDL may be selectively increased.

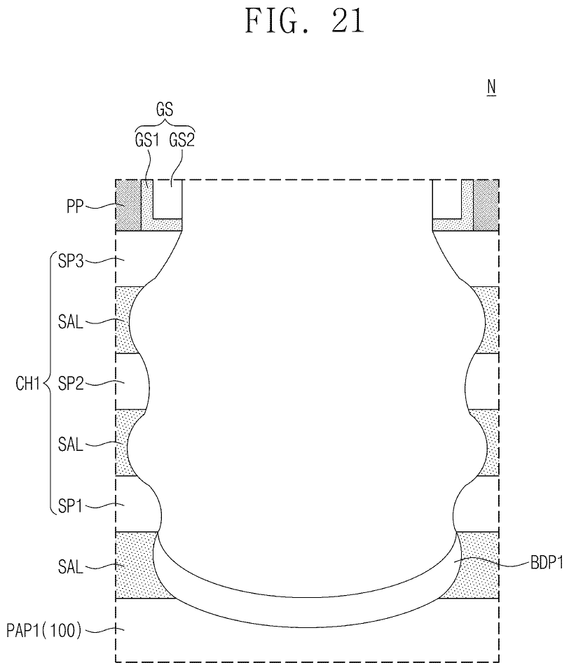

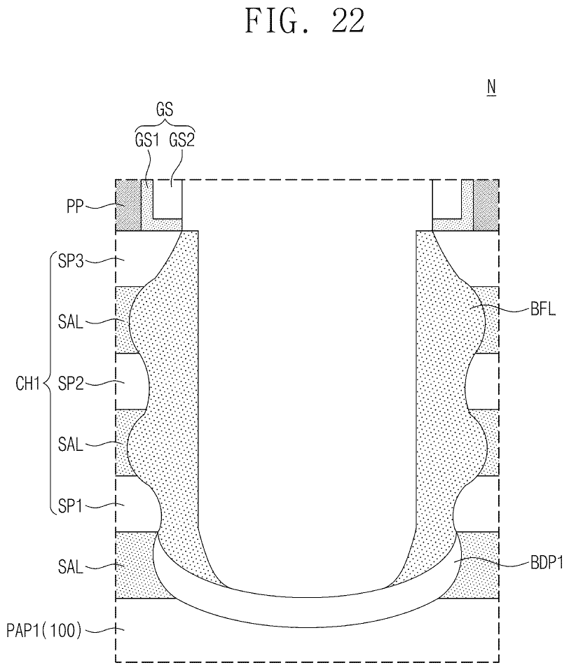

Referring to FIG. 21, the first lower insulating pattern BDP1 may be formed by performing an etching process on the preliminary insulating layer PBDL. The etching process may be a dry etching process or a wet etching process. Since the lower portion EP of the preliminary insulating layer PBDL has a density increased by the plasma, the lower portion EP of the preliminary insulating layer PBDL may have a high etch resistant property compared to remaining portions of the preliminary insulating layer PBDL. Thus, after the etching process, a portion of the lower portion EP may be left to form the first lower insulating pattern BDP1.

The first lower insulating pattern BDP1 may be extended from the bottom surface of the first recess RS1 to a side surface of the lowermost one of the sacrificial layers SAL. For example, the uppermost surface of the first lower insulating pattern BDP1 may be at substantially the same level as a top surface of the lowermost one of the sacrificial layers SAL. In some cases, the uppermost surface of the first lower insulating pattern BDP1 may be at a level substantially equal to or lower than the bottom surface of the first semiconductor pattern SP1.

Referring to FIG. 22, the buffer layer BFL may be formed by performing a first SEG process on an inner side surface of the first recess RS1. In the first SEG process, a gas of HCl or Cl₂ may be used as an etchant gas, and a gas of SiH₄, SiCl₂H₂, SiHCl₃, or Si₂H₆ may be used as a silicon source gas.

For example, the buffer layer BFL may be grown using the first, second, and third semiconductor patterns SP1, SP2, and SP3 and the sacrificial layers SAL as a seed layer. The lowermost one of the sacrificial layer SAL, which disposed on and adjacent to the first lower insulating pattern BDP1, might not be used as the seed layer in the process of growing the buffer layer BFL. Since the buffer layer BFL is grown using the first semiconductor pattern SP1 as a seed layer, the buffer layer BFL may cover a portion of the first lower insulating pattern BDP1.

The buffer layer BFL may include undoped silicon, silicon-germanium (SiGe), or silicon carbide (SiC). The buffer layer BFL may include a relatively low concentration of dopants. For example, the dopants may be germanium (Ge). For example, the buffer layer BFL may have the first doping concentration C1 described with reference to FIG. 6C. For example, the first doping concentration C1 may range from 0 at % to 0.1 at %.

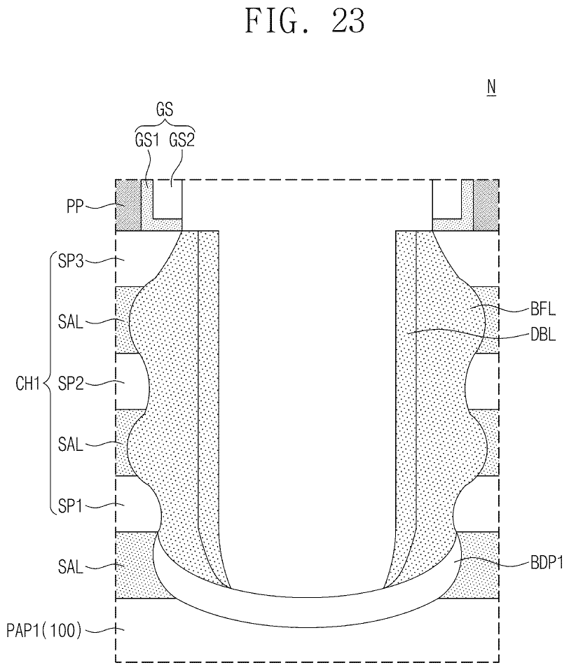

Referring to FIG. 23, the barrier layer DBL may be formed by performing a second SEG process on an inner side surface of the buffer layer BFL. In the second SEG process, a gas of HCl or Cl₂ may be used as an etchant gas, and a gas of SiH₄, SiCl₂H₂, SiHCl₃, or Si₂H₆ may be used as a silicon source gas.

For example, the barrier layer DBL may be grown using the buffer layer BFL as a seed layer. The barrier layer DBL may be formed to have a uniform thickness on the inner side surface of the buffer layer BFL. In some cases, the barrier layer DBL may have a thickness that decreases in the direction toward the first lower insulating pattern BDP1. The barrier layer DBL may be formed along the inner side surface of the buffer layer BFL but might not cover the first lower insulating pattern BDP1.

The barrier layer DBL may include silicon-phosphorus (SiP), silicon-arsenic (SiAs), or silicon-antimony (SiSb). The barrier layer DBL may include a low concentration of dopants. The dopants may be, for example, phosphorus (P), arsenic (As), or antimony (Sb). In an embodiment, the barrier layer DBL may be formed to have the second doping concentration C2 described with reference to FIG. 6C. For example, the second doping concentration C2 may range from 0.1 at % to 4 at %. The second doping concentration C2 of the barrier layer DBL may be higher than the first doping concentration C1 of the buffer layer BFL.

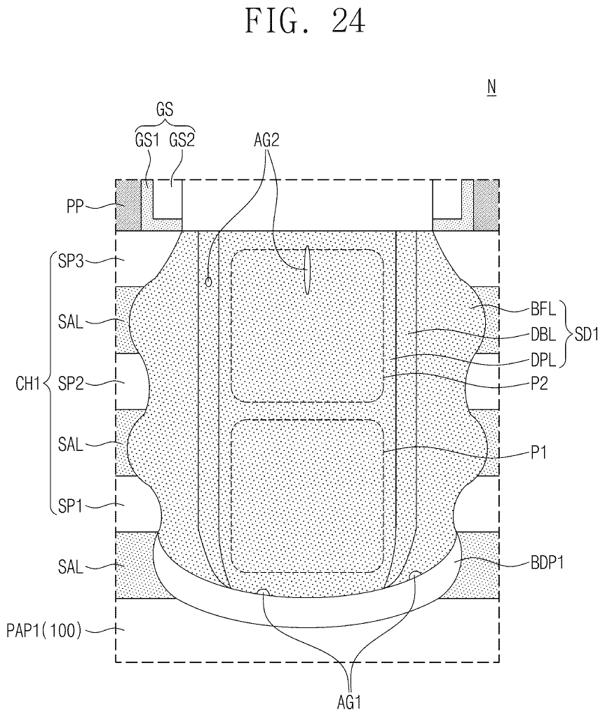

Referring to FIG. 24, the doping layer DPL may be formed by performing a third SEG process on an inner side surface of the barrier layer DBL. In the third SEG process, a gas of HCl or Cl₂ may be used as an etchant gas, and a gas of SiH₄, SiCl₂H₂, SiHCl₃ or Si₂H₆ may be used as a silicon source gas.

For example, the doping layer DPL may be grown using the barrier layer DBL as a seed layer. The doping layer DPL may be formed between the barrier layers DBL. The doping layer DPL may fill the space in the barrier layers DBL. The doping layer DPL may be grown from an inner side surface of the barrier layers DBL to fill an empty space between the barrier layers DBL. In some cases, a top surface of the doping layer DPL may be substantially coplanar with top surfaces of the third semiconductor pattern SP3, the barrier layers DBL, and the buffer layer BFL.

The doping layer DPL may be grown from the inner side surface of the barrier layer DBL to fill center and lower portions of the first recess RS1. In some cases, a first air gap pattern AG1 may be formed between the doping layer DPL, which is grown from the inner side surface of the barrier layer DBL, and the first lower insulating pattern BDP1. For example, the first air gap pattern AG1 may be an empty space, which may be formed based on an aspect ratio of the first recess RS1 or a step coverage of the doping layer DPL. In an embodiment, the first air gap pattern AG1 may be a void. Similar to the doping layer DPL, the first air gap pattern AG1 may also be formed between the buffer layer BFL and the first lower insulating pattern BDP1.

In some cases, a second air gap pattern AG2 may be formed in the doping layer DPL, which is grown from the inner side surface of the barrier layer DBL. For example, the second air gap pattern AG2 may be an empty space, which may be formed based on the aspect ratio of the first recess RS1 or the step coverage of the doping layer DPL. In an embodiment, the second air gap pattern AG2 may be a void. Similar to the doping layer DPL, the second air gap pattern AG2 may also be formed in the barrier layer DBL.

The first and second air gap patterns AG1 and AG2 may have various shapes that represent the void. For example, the first air gap pattern AG1 may have a circular or elliptical shape, and the second air gap pattern AG2 may have a shape of seam or slit.

The doping layer DPL may include a first portion P1 and a second portion P2. For example, the first portion P1 is adjacent to the first semiconductor pattern SP1. In some cases, the first portion P1 is at a lower portion of the doping layer DPL. In some cases, the first portion P1 is adjacent to the first lower insulating pattern BDP1. For example, the second portion P2 is adjacent to the second and third semiconductor patterns SP2 and SP3. For example, the second portion is at an upper portion of the doping layer DPL. The second portion P2 may include the second air gap pattern AG2.

The doping layer DPL may include silicon-phosphorus (SiP) or silicon-arsenic-phosphorus (SiAsP). The doping layer DPL may include a high concentration of dopants. For example, the dopants may be phosphorus (P) or arsenic (As). For example, the doping layer DPL may have the third doping concentration C3 described with reference to FIG. 6C. The third doping concentration C3 may range from 4 at % to 12 at %. For example, the third doping concentration C3 of the doping layer DPL may be higher than the second doping concentration C2 of the barrier layer DBL. For example, the third doping concentration C3 of the doping layer DPL may be higher than the first doping concentration C1 of the buffer layer BFL.

Referring to FIG. 6B, the third doping concentration C3 may gradually decrease as a measurement point changes from the first portion P1 to the second portion P2. For example, a region near the first semiconductor pattern SP1 has a relatively high doping concentration (e.g., of phosphorus (P)), and a region near the second and third semiconductor patterns SP2 and SP3 has a relatively low doping concentration.

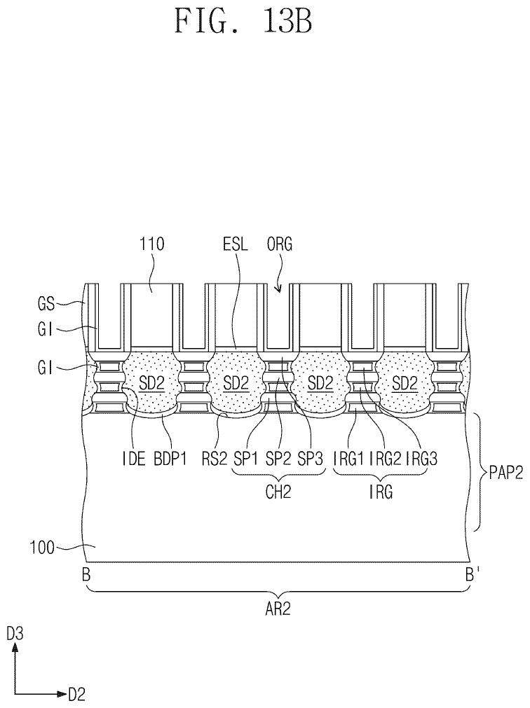

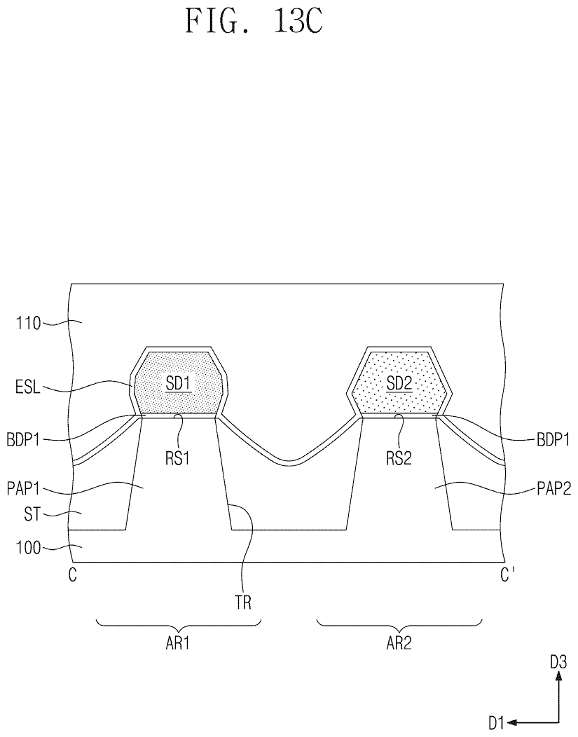

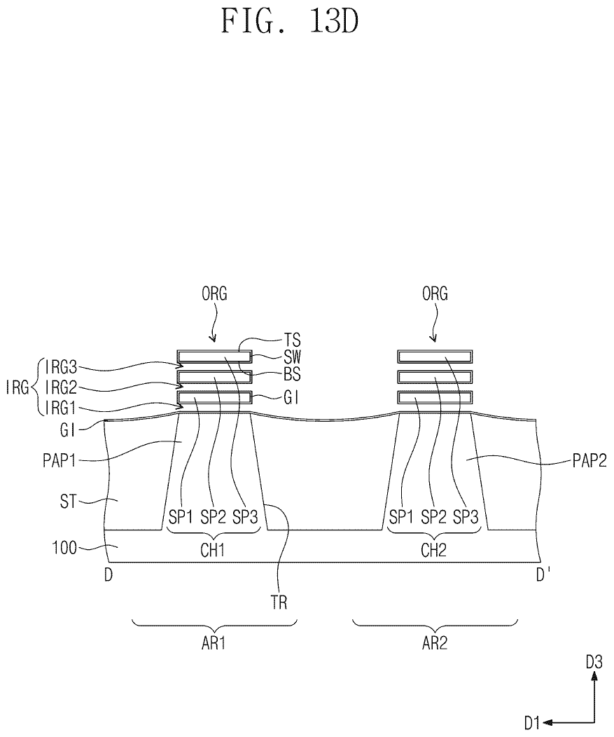

Referring to FIGS. 13A to 13D, the etch stop layer ESL may be formed to cover the first and second source/drain patterns SD1 and SD2. The etch stop layer ESL may be extended from the first and second source/drain patterns SD1 and SD2 to cover the device isolation layer ST (e.g., see FIG. 13C). The etch stop layer ESL may be conformally formed to have a uniform thickness.

The first interlayer insulating layer 110 may be formed to cover the first and second source/drain patterns SD1 and SD2, the hard mask patterns MP, and the gate spacers GS. For example, the first interlayer insulating layer 110 may be formed to cover the etch stop layer ESL, which is formed on the first and second source/drain patterns SD1 and SD2, the hard mask patterns MP, and the gate spacers GS. In an embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. In some cases, the hard mask patterns MP may be removed during the planarization process.

In an embodiment, the exposed sacrificial patterns PP may be selectively removed. As a result of the removal of the sacrificial patterns PP, an outer region ORG may be formed to expose the first and second channel patterns CH1 and CH2 (e.g., see FIG. 13D). The removal of the sacrificial patterns PP may include a wet etching process which is performed using an etching solution capable of selectively etching polysilicon.

Inner regions IRG may be formed by selectively removing the sacrificial layers SAL exposed through the outer region ORG (e.g., see FIG. 13D). For example, an etching process of selectively etching the sacrificial layers SAL may be performed to remove the sacrificial layers SAL and maintain the first, second, and third semiconductor patterns SP1, SP2, and SP3. An etch recipe for the etching process may be chosen to etch a layer (e.g., a silicon germanium layer), which is formed to have a relatively high germanium concentration, at a high etch rate. For example, the etching process may be chosen to have a high etch rate to a silicon germanium layer whose germanium concentration is higher than 10 at %.

During the etching process, the sacrificial layers SAL on the first and second active regions AR1 and AR2 may be removed. The etching process may be a wet etching process. An etchant material, which is used in the etching process, may be chosen to quickly remove the sacrificial layer SAL having a relatively high germanium concentration. In an embodiment, an upper portion of the gate spacer GS may be removed during the etching process.

Referring to FIG. 13D, as a result of the selective removal of the sacrificial layers SAL, the stacked first, second, and third semiconductor patterns SP1, SP2, and SP3 may be remained on each of the first and second active patterns PAP1 and PAP2. Empty regions, which are formed by removing the sacrificial layers SAL, may form first, second, and third inner regions IRG1, IRG2, and IRG3, respectively.

For example, the first inner region IRG1 may be formed between the active pattern PAP1 or PAP2 and the first semiconductor pattern SP1. In some cases, the first inner region IRG1 may be formed between the gate insulating layer GI and the first semiconductor pattern SP1. For example, the second inner region IRG2 may be formed between the first semiconductor pattern SP1 and the second semiconductor pattern SP2. For example, the third inner region IRG3 may be formed between the second semiconductor pattern SP2 and the third semiconductor pattern SP3. A height of the first inner region IRG1 measured in the third direction D3 may be larger than a height of each of the second and third inner regions IRG2 and IRG3 measured in the third direction D3.

Referring to FIGS. 13A to 13D, the gate insulating layer GI may be formed on the exposed first, second, and third semiconductor patterns SP1, SP2, and SP3. The gate insulating layer GI may be formed to surround each of the first, second, and third semiconductor patterns SP1, SP2, and SP3. For example, the gate insulating layer GI may be formed on a top surface TS, side surfaces SW, and a bottom surface BS of each of the first, second, and third semiconductor patterns SP1, SP2, and SP3. The gate insulating layer GI may be formed in each of the first, second, and third inner regions IRG1, IRG2, and IRG3. The gate insulating layer GI may be formed in the outer region ORG. In some cases, the gate insulating layer GI may be formed on the device isolation layer ST. In some cases, a high-k dielectric layer may be formed on the gate insulating layer GI.

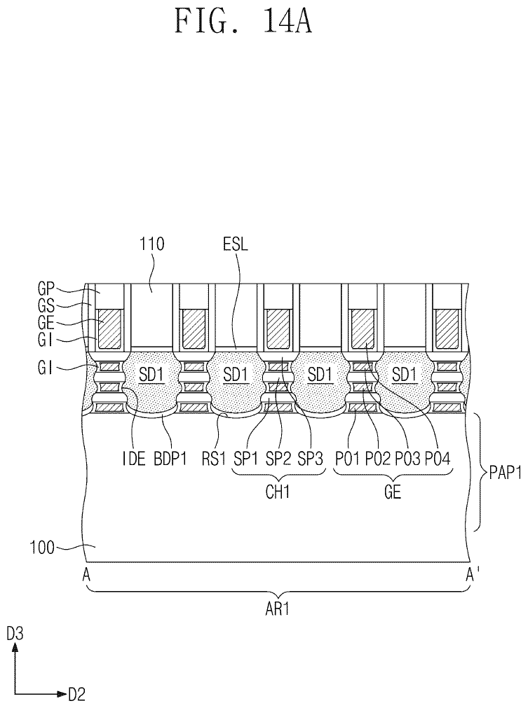

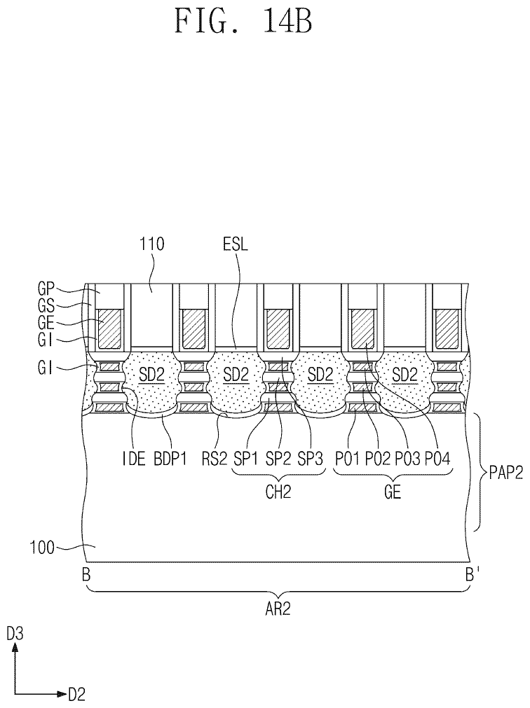

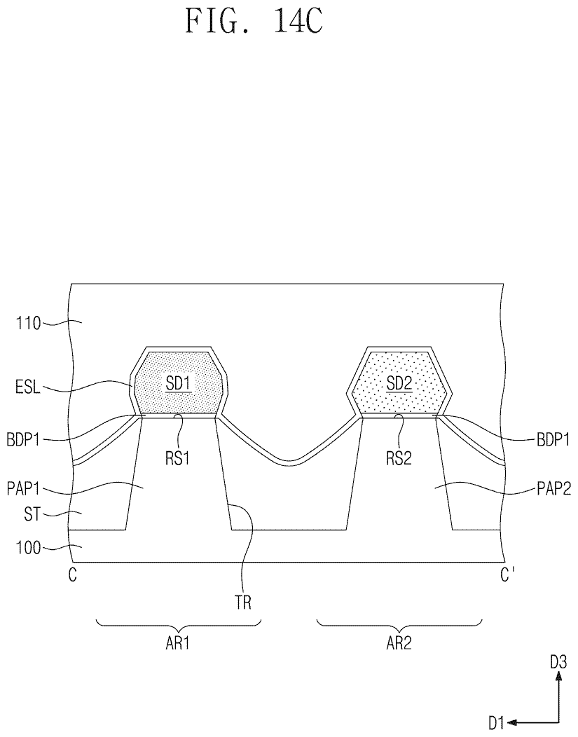

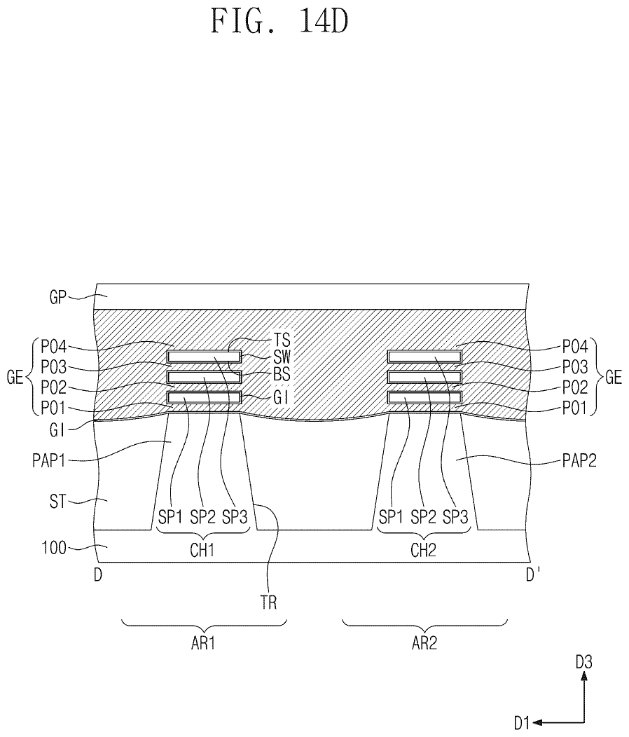

Referring to FIGS. 14A to 14D, the gate electrode GE may be formed on the gate insulating layer GI. For example, the gate electrode GE includes first, second, third, and fourth inner electrodes PO1, PO2, PO3, and PO4. For example, the gate electrode GE may include the first, second, and third inner electrodes PO1, PO2, and PO3, which are formed in the first, second, and third inner regions IRG1, IRG2, and IRG3, respectively, and the outer electrode PO4, which is formed in the outer region ORG.

For example, the formation of the gate electrode GE may include forming a first metal layer in the first, second, and third inner regions IRG1, IRG2, and IRG3 and the outer region ORG, forming a second metal layer on the first metal layer, and performing a chemical mechanical polishing (CMP) process on the first and second metal layers using the first interlayer insulating layer 110 as a stopper. The first metal layer may include a metal nitride layer, and the second metal layer may include a low resistance metallic material.

The formation of the first and second metal layers may include depositing the first and second metal layers to cover the gate insulating layer GI, the first interlayer insulating layer 110, and a top surface of the gate spacer GS. The CMP process on the first and second metal layers may be performed to remove the first and second metal layers using slurry.

The gate electrode GE (or the fourth inner electrode PO4) may be recessed to have a reduced height. The gate capping pattern GP may be formed on the recessed gate electrode GE. The gate capping pattern GP may include a silicon-nitride-based insulating material. In some cases, a top surface of the gate capping pattern GP may be at a same level as the top surface of the first interlayer insulating layer 110 and the top surface of the gate spacer GS.

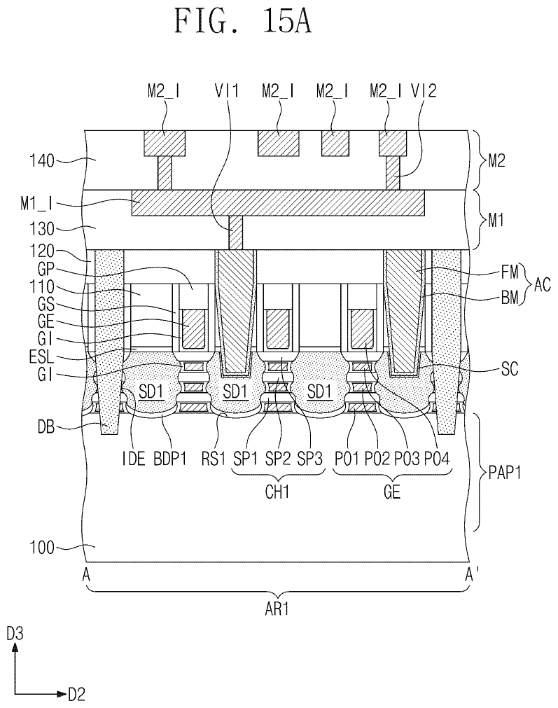

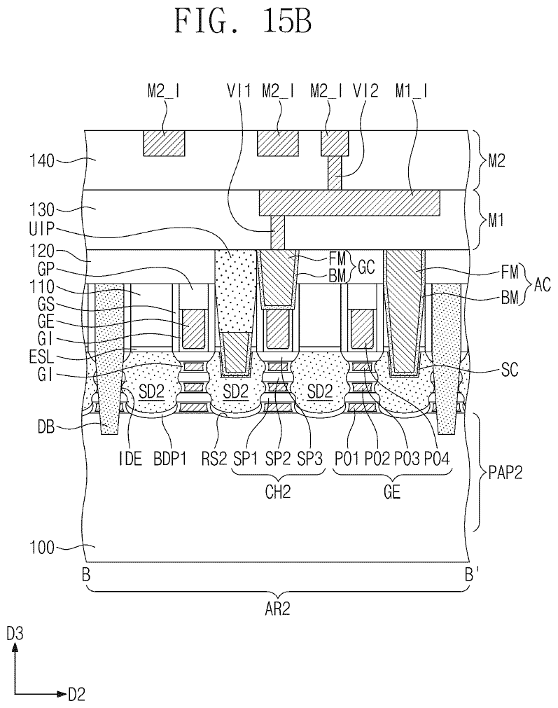

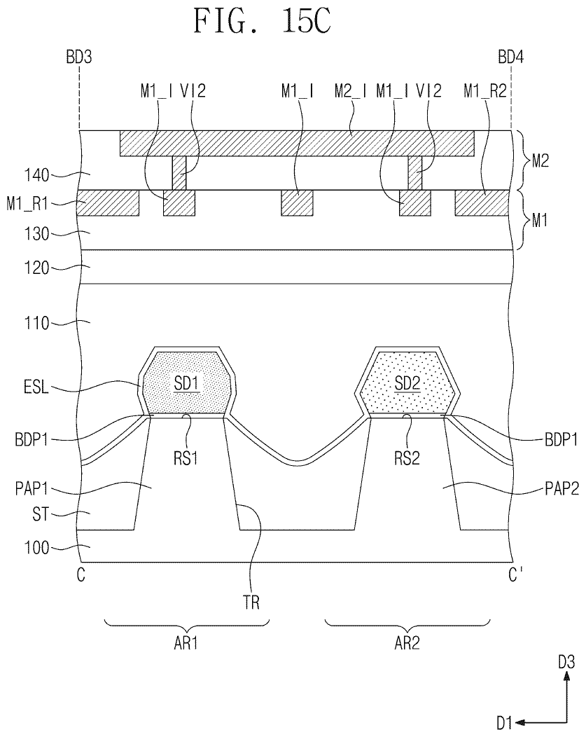

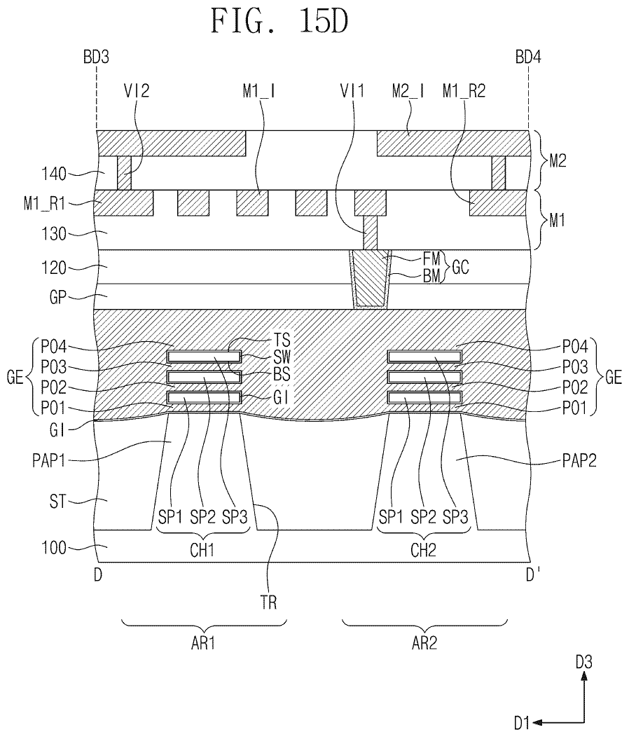

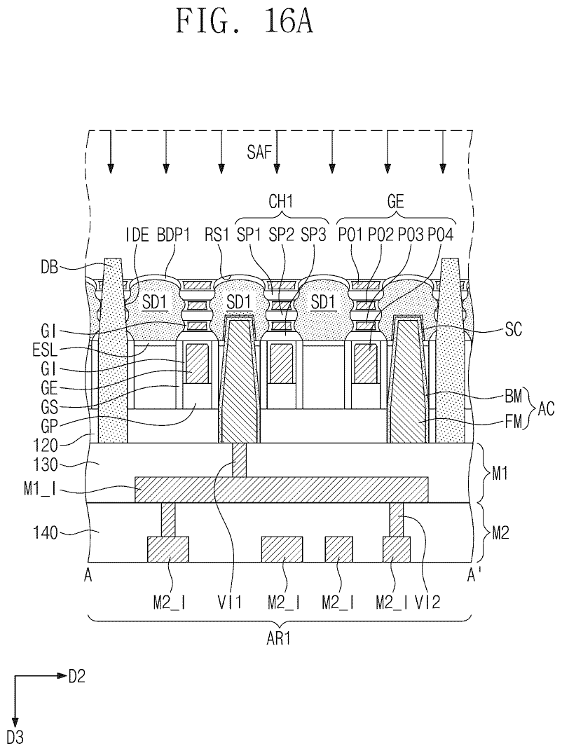

Referring to FIGS. 15A to 15D, the second interlayer insulating layer 120 may be formed on the first interlayer insulating layer 110. The second interlayer insulating layer 120 may include a silicon oxide layer. An etch mask may be deposited on the second interlayer insulating layer 120. Then, the first and second recess regions, which penetrates the first and second interlayer insulating layers 110 and 120 and the etch stop layer ESL, may be formed by an etching process using the etch mask. In an embodiment, the first and second recess regions may be formed by a dry etching process.

The first recess region may penetrate the first and second interlayer insulating layers 110 and 120 and the etch stop layer ESL and extend to an upper portion of the first source/drain pattern SD1. For example, the first recess region may be inserted into the first source/drain pattern SD1. The second recess region may penetrate the first and second interlayer insulating layers 110 and 120 and the etch stop layer ESL and extend to an upper portion of the second source/drain pattern SD2. For example, the second recess region may be inserted into the second source/drain pattern SD2.

The active contacts AC may be formed to penetrate the first and second interlayer insulating layers 110 and 120 and the etch stop layer ESL and may be electrically connected to the first and second source/drain patterns SD1 and SD2. For example, the active contact AC may be formed on each of the first and second recess regions. The gate contact GC may be formed to penetrate the second interlayer insulating layer 120 and the gate capping pattern GP and may be electrically connected to the gate electrode GE (or the outer electrode PO4 of the gate electrode). In some cases, a metal-semiconductor compound layer SC is formed between the active contact Ac and the first and second source/drain patterns SD1 and SD2.

The formation of the active and gate contacts AC and GC may include forming the barrier pattern BM and forming the conductive pattern FM on the barrier pattern BM. The barrier pattern BM may be conformally formed and may include a metal layer and a metal nitride layer. The conductive patterns FM may include a low resistance metallic material. The conductive patterns FM may fill a space in the barrier pattern BM.

Referring to FIG. 15B, the active contact AC, which is connected to the second source/drain pattern SD2, may include the upper insulating pattern UIP. The upper insulating pattern UIP may prevent a short phenomenon or a coupling phenomenon between the gate contact GC and the active contact AC, which are adjacent to each other. The upper insulating pattern UIP may include an insulating material.

The division structures DB may be respectively formed on the first and second borders BD1 and BD2 of the single height cell SHC. The division structure DB may penetrate the first interlayer insulating layer 110 and the gate electrode GE and may be extended into the active pattern PAP1 or PAP2. The division structure DB may include one or more insulating materials (e.g., silicon oxide or silicon nitride). In an embodiment, the division structure DB may include one or more metallic materials.

The third interlayer insulating layer 130 may be formed on the active contacts AC and the gate contact GC. The first metal layer M1 may be formed in the third interlayer insulating layer 130. The first metal layer M1 may include the first interconnection line M1_I, which is electrically connected to at least one of the active and gate contacts AC and GC through first vias VI1. The fourth interlayer insulating layer 140 may be formed on the third interlayer insulating layer 130. The second metal layer M2 may be formed in the fourth interlayer insulating layer 140. In some cases, the second metal layer M2 may be electrically connected to the first metal layer M1 through second vias VI2.

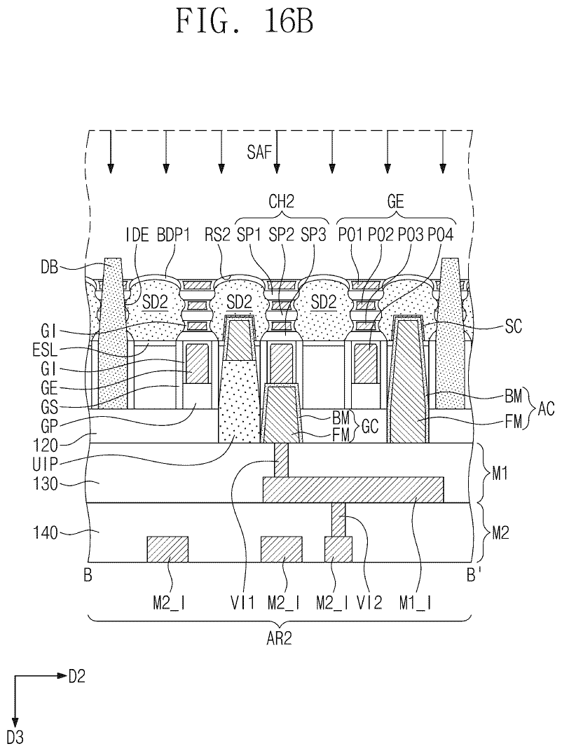

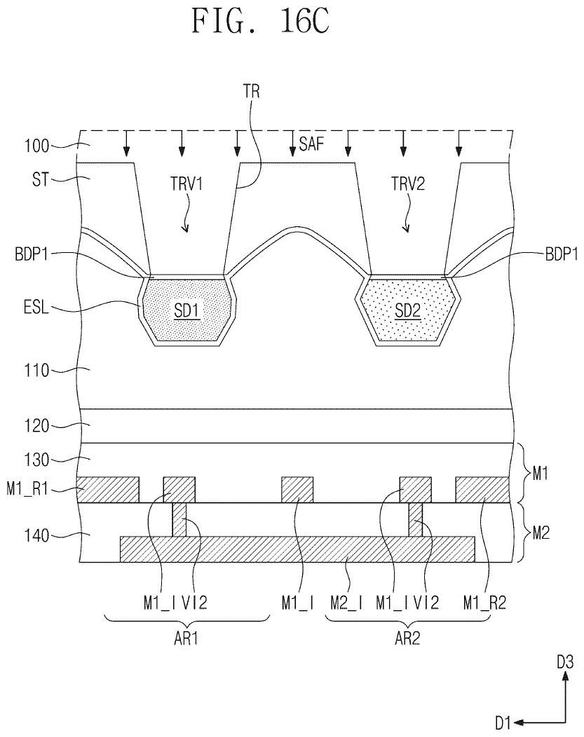

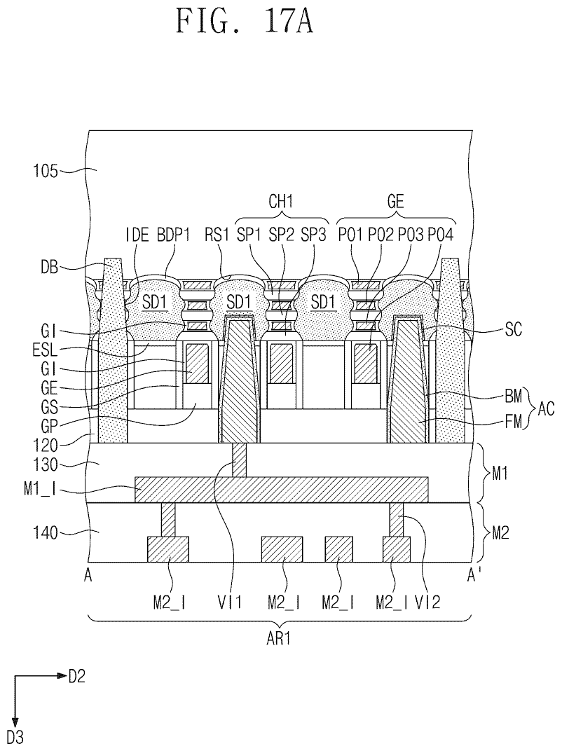

Referring to FIGS. 16A to 16C, when a BEOL process is completed, a semiconductor substrate 100 may be inverted such that a bottom surface of the semiconductor substrate 100 is exposed to the outside. The exposed semiconductor substrate 100 may be removed.

In an embodiment, the removal of the semiconductor substrate 100 may include performing a planarization process SAF on the bottom surface of the semiconductor substrate 100 to reduce a thickness of the semiconductor substrate 100, performing a cleaning process of selectively removing silicon (Si) on the semiconductor substrate 100, and performing a first etching process of selectively removing silicon (Si) in the first and second active patterns PAP1 and PAP2. The cleaning process may be performed to expose the device isolation layer ST. The first etching process may be a dry etching process or a wet etching process.

As a result of the removal of the semiconductor substrate 100, a first backside trench TRV1 may be formed in a region where the first active pattern PAP1 is present. As a result of the removal of the semiconductor substrate 100, a second backside trench TRV2 may be formed in a region where the second active pattern PAP2 is present (e.g., see FIG. 16C).

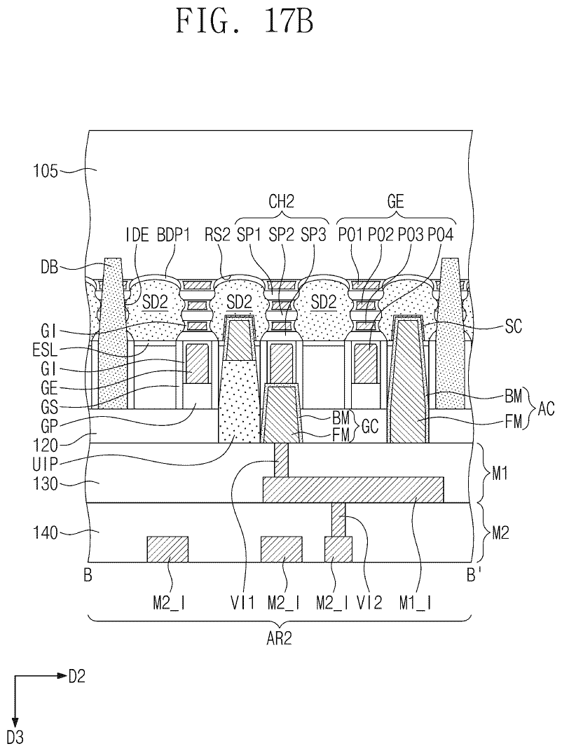

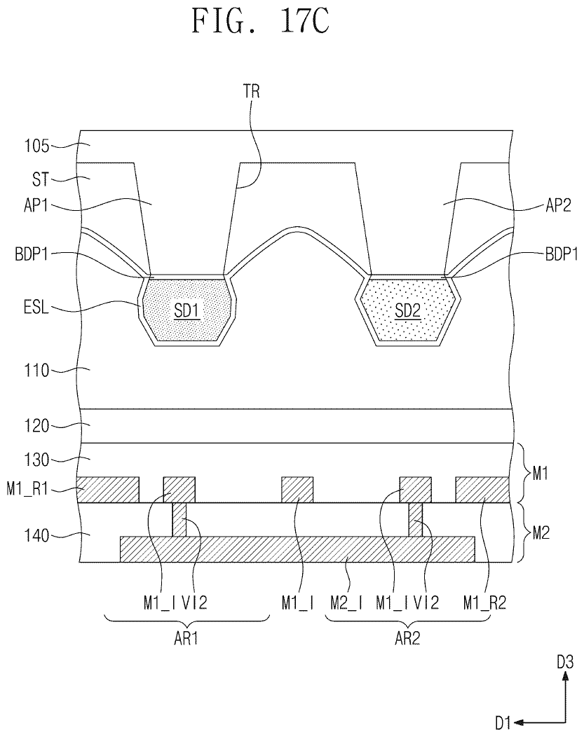

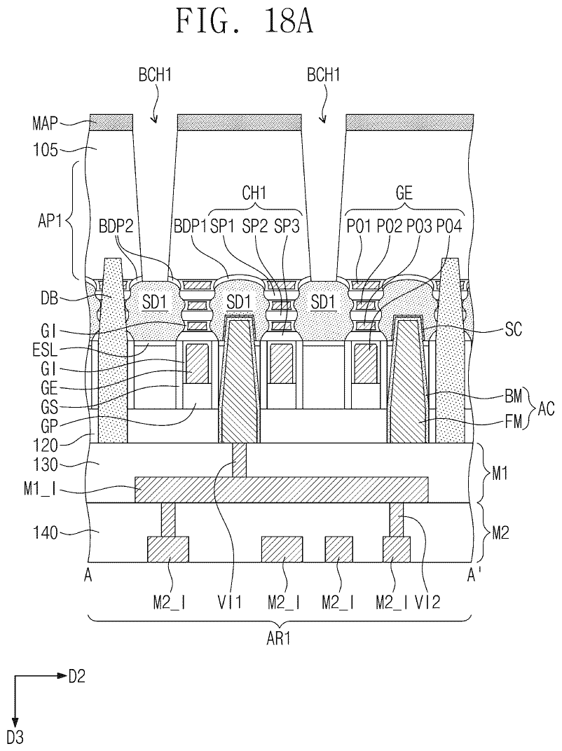

Referring to FIGS. 17A to 17C, the substrate 105 may be formed by filling an empty region, which is formed by removing the semiconductor substrate 100, with an insulating material. The substrate 105 may include a silicon-based insulating layer. For example, the substrate 105 may include a silicon nitride layer or a silicon oxide layer. The first insulating pattern AP1 may fill the first backside trench TRV1, and the second insulating pattern AP2 may fill the second backside trench TRV2.

First mask patterns MAP may be formed on the substrate 105. The first mask patterns MAP may be formed through a photolithography process. Each of the first mask patterns MAP may be a line-shaped or bar-shaped pattern, which is extended in the first direction D1.

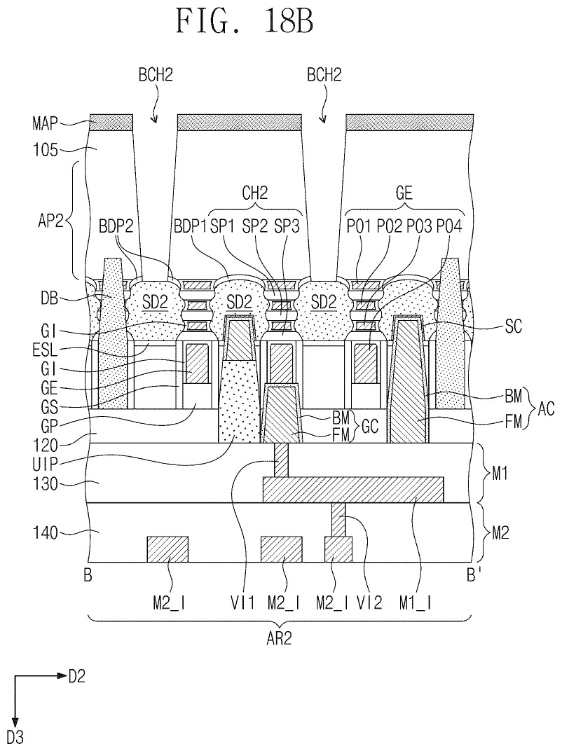

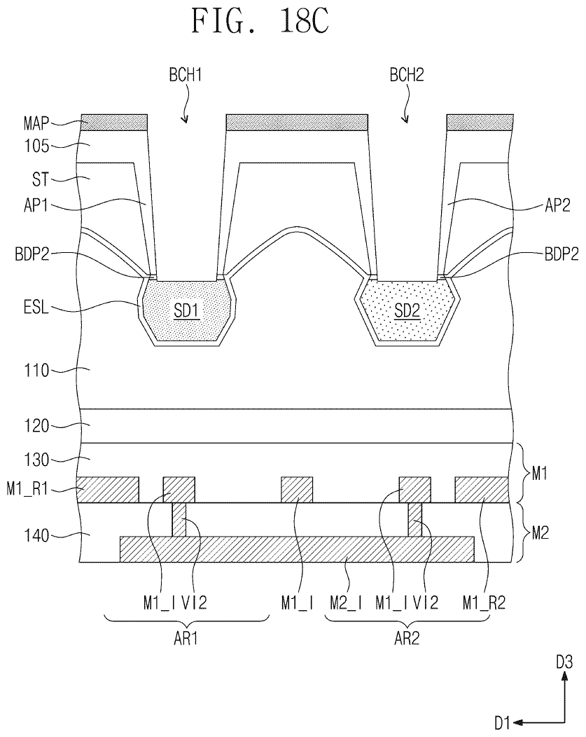

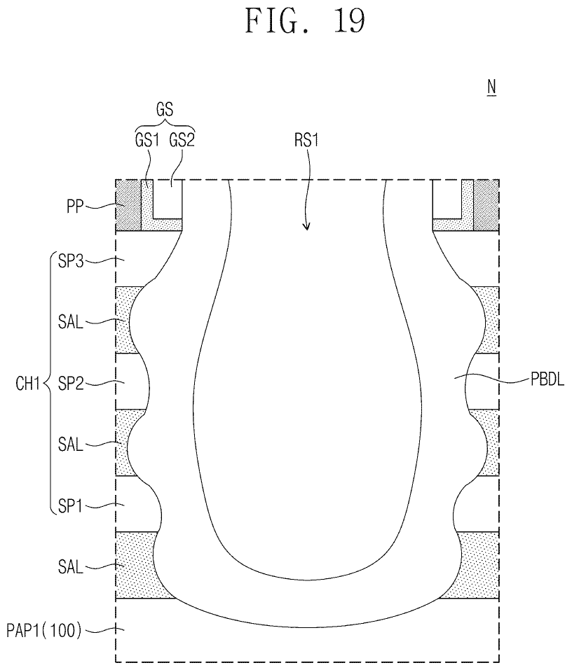

Referring to FIGS. 18A to 18C, a second etching process using the first mask patterns MAP as an etch mask may be performed on the substrate 105 to form first backside holes BCH1 on the first active region AR1. Second backside holes BCH2 may be formed on the second active region AR2 by the second etching process using the first mask patterns MAP as the etch mask. In some cases, the second etching process may be a dry etching process. The second etching process may be an anisotropic etching process.

The first lower insulating patterns BDP1 may be slightly removed by an etchant, which is supplied through the first and second backside holes BCH1 and BCH2, in the second etching process. In an embodiment, the first and second source/drain patterns SD1 and SD2 may be partially recessed by the etchant, which is supplied through a region between remaining portions of the first lower insulating patterns BDP1. For example, the bottom surface of the first and second source/drain patterns SD1 and SD2 may be partially exposed.

Referring to FIGS. 5A to 5D, a strip process or an ashing process may be performed to remove the first mask patterns MAP. After the removal of the first mask patterns MAP, the backside active contact BAC may be formed in each of the first and second backside holes BCH1 and BCH2. The backside active contact BAC may be formed to penetrate the substrate 105 and may be electrically connected to each of the first and second source/drain patterns. For example, the backside active contact BAC may be inserted into each of the first and second source/drain patterns SD1 and SD2. For example, the backside active contact BAC may be in direct contact with the bottom surfaces of the first and second source/drain patterns SD1 and SD2.

The formation of the backside active contacts BAC may include forming the barrier pattern BM and forming the conductive pattern FM on the barrier pattern BM. For example, the conductive pattern FM may fill the space in the barrier pattern BM. The barrier pattern BM may be conformally formed and may include a metal layer and a metal nitride layer. The conductive pattern FM may include a low resistance metallic material. The barrier and conductive patterns BM and FM may include the same materials as the barrier and conductive patterns in each of the active and gate contacts AC and GC described above.

For example, the formation of the backside active contacts BAC may include forming the barrier pattern BM, forming the conductive pattern FM on the barrier pattern BM, and performing a chemical mechanical polishing (CMP) process on the barrier and conductive patterns BM and FM. In some cases, the bottom surface of the substrate 105 is used as a stopper for the formation of the backside active contacts BAC. The CMP process may be performed to remove the barrier pattern BM and the conductive pattern FM using slurry.

The lower power line VPR may be formed in a lower portion of the substrate 105. For example, the lower power line VPR may be formed on a lower portion of the substrate 105. In some cases, the bottom surface of the lower power line VPR may be coplanar with the bottom surface of the substrate 105. The lower power line VPR may be electrically connected to each of the first and second source/drain patterns SD1 and SD2 through the backside active contact BAC. The lower power line VPR may be formed through a separate process. In an embodiment, the lower power line VPR may be formed by a single damascene process. The semiconductor device according to the present embodiment may be fabricated using a sub-20 nm process.

The power delivery network layer PDN may be formed below the substrate 105 and the lower power line VPR. In some cases, the power delivery network layer PDN may cover the substrate 105 and the lower power line VPR. The power delivery network layer PDN may include a plurality of lower interconnection lines, which are electrically connected to the lower power line VPR. In an embodiment, the power delivery network layer PDN may include an interconnection network, which is used to apply a source voltage or a drain voltage to the lower power line VPR.

According to an embodiment of the inventive concept, a three-dimensional field effect transistor may include a lower insulating pattern, which is formed below a source/drain pattern. In some cases, the three-dimensional field effect transistor may include an active contact, which is connected to a highly-doped region of a source/drain pattern through a backside surface of a substrate. A backside silicide pattern disposed between a backside active contact and the source/drain pattern may be formed in the highly doped region. Thus, a contact resistance between the backside active contact and the source/drain pattern is reduced. Accordingly, the electrical characteristics of the semiconductor device is increased.

According to an embodiment of the inventive concept, a three-dimensional field effect transistor may include the active contact, which is connected to the source/drain pattern through the backside surface of the substrate. As a result, a pattern density of a metal line layer, which is formed on a frontside surface of the substrate, may be lowered. For example, the technical difficulties in a metal patterning process of forming an interconnection pattern is reduced. In addition, since the pattern density of the metal line layer is lowered, a coupling phenomenon, which occurs when the active contact is adjacent to a gate contact, is prevented. Accordingly, the efficiency in a process of fabricating the semiconductor device and the reliability of the semiconductor device is increased.

While example embodiments of the inventive concept have been shown and described, it will be understood by one of ordinary skill in the art that variations in form and detail may be made therein without departing from the spirit and scope of the attached claims.

What is claimed is:

1. A semiconductor device, comprising:
a substrate including an insulating pattern;
a channel pattern disposed on the insulating pattern, wherein the channel pattern comprises a plurality of semiconductor patterns vertically stacked and spaced apart from each other;
a source/drain pattern disposed adjacent to the plurality of semiconductor patterns;
a gate electrode disposed on the plurality of semiconductor patterns;
a lower power line disposed in a lower portion of the substrate, wherein a bottom surface of the lower power line is coplanar with a bottom surface of the substrate;
a lower insulating pattern disposed between the source/drain pattern and the insulating pattern;
a backside active contact disposed below the source/drain pattern, wherein the backside active contact penetrates the substrate and the lower insulating pattern and electrically connects the lower power line and the source/drain pattern; and
a backside silicide pattern disposed between the source/drain pattern and the backside active contact,
wherein the source/drain pattern comprises:
a buffer layer disposed on side surfaces of the plurality of semiconductor patterns and the gate electrode;
a barrier layer disposed on an inner side surface of the buffer layer; and
a doping layer filling a space enclosed by the barrier layer,
wherein the backside active contact and the backside silicide pattern are vertically overlapped with the doping layer.

2. The semiconductor device of claim 1, wherein the backside silicide pattern directly contacts the doping layer.

3. The semiconductor device of claim 2, wherein the backside silicide pattern is not vertically overlapped with the buffer layer and the barrier layer, and
the backside silicide pattern is not in direct contact with the buffer layer and the barrier layer.

4. The semiconductor device of claim 1, wherein an uppermost surface of the lower insulating pattern is at a level lower than a bottom surface of a lowermost one of the plurality of semiconductor patterns.

5. The semiconductor device of claim 1, wherein the lower insulating pattern includes SiNₓ, SiOC, SiOCN, SiON, SiO, SiBCN, SiBC, or combinations thereof.

6. The semiconductor device of claim 1, further comprising:
a void disposed between the source/drain pattern and the lower insulating pattern.

7. The semiconductor device of claim 1, further comprising:
an etch stop layer disposed on the source/drain pattern, wherein the etch stop layer includes SiN, SiCN, SiOCN, SiBN, SiBC, or combinations thereof.

8. The semiconductor device of claim 7, wherein a thickness of the etch stop layer measured in a first direction ranges from 1 nm to 5 nm, and the first direction is in a direction perpendicular to the substrate.

9. The semiconductor device of claim 1, wherein a side surface of the source/drain pattern has a wavy profile.

10. The semiconductor device of claim 1, wherein the source/drain pattern further comprises:
a control layer disposed between the buffer layer and the barrier layer, wherein the control layer comprises silicon carbide (SiC).

11. The semiconductor device of claim 10, wherein a carbon concentration of the control layer ranges from 0.1 at % to 0.5 at %.

12. The semiconductor device of claim 10, wherein the source/drain pattern comprises a stacking fault, and
the stacking fault is disposed in an upper portion of the source/drain pattern.

13. A semiconductor device, comprising:
a substrate;
a lower power line disposed in a lower portion of the substrate;
a lower insulating pattern disposed on the substrate;
a source/drain pattern disposed on the lower insulating pattern; and
a backside active contact disposed below the source/drain pattern, wherein the backside active contact penetrates the substrate and electrically connects the lower power line and the source/drain pattern,
wherein the source/drain pattern comprises:
a buffer layer disposed on the lower insulating pattern, wherein the buffer layer has a first doping concentration;
a barrier layer disposed on an inner side surface of the buffer layer, wherein the barrier layer has a second doping concentration; and
a doping layer filling a space enclosed by the buffer layer, wherein the doping layer has a third doping concentration,
wherein the backside active contact is electrically connected to the doping layer, and
wherein the third doping concentration is higher than the first doping concentration and the second doping concentration.

14. The semiconductor device of claim 13, wherein the second doping concentration is higher than the first doping concentration.

15. The semiconductor device of claim 13, wherein the second doping concentration ranges from 0.1 at % to 4 at %.

16. The semiconductor device of claim 13, wherein the third doping concentration ranges from 4 at % to 12 at %.

17. The semiconductor device of claim 13, wherein each of the barrier layer and the doping layer comprises a void, and
wherein a volume of the void is 0.001 to 0.02 times a volume of the source/drain pattern.

18. A semiconductor device, comprising:
an insulating substrate;
a channel pattern disposed on the insulating substrate, wherein the channel pattern comprises a plurality of semiconductor patterns vertically stacked and spaced apart from each other;
a pair of source/drain patterns connected to the channel pattern, wherein the pair of source/drain patterns comprising a first sub-source/drain pattern and a second sub-source/drain pattern;
a first lower insulating pattern disposed below the first sub-source/drain pattern;
a second lower insulating pattern disposed below the second sub-source/drain pattern;
an etch stop layer disposed on the second sub-source/drain pattern;
a gate electrode disposed on the channel pattern, wherein the gate electrode comprises inner electrodes interposed between adjacent ones of the plurality of semiconductor patterns and an outer electrode disposed on an uppermost one of the plurality of semiconductor patterns;
a gate insulating layer interposed between the gate electrode and the channel pattern;
a gate spacer disposed on a side surface of the gate electrode;
a gate capping pattern disposed on a top surface of the gate electrode;
an interlayer insulating layer covering the pair of source/drain patterns, the gate capping pattern, and the etch stop layer;
an active contact disposed on the insulating substrate, wherein the active contact penetrates the interlayer insulating layer and is electrically connected to the first sub-source/drain pattern;
a first metal layer disposed on the interlayer insulating layer, wherein the first metal layer comprises a first interconnection line electrically connected to the active contact;
a second metal layer disposed on the first metal layer, wherein the second metal layer comprises a second interconnection line electrically connected to the first metal layer;
a lower power line disposed in a lower portion of the insulating substrate, wherein a bottom surface of the lower power line is coplanar with a bottom surface of the insulating substrate;
a backside active contact disposed below the second sub-source/drain pattern, wherein the backside active contact penetrates the insulating substrate and electrically connects the lower power line to the second sub-source/drain pattern; and
a backside silicide pattern disposed between the second sub-source/drain pattern and the backside active contact,
wherein the first lower insulating pattern is extended from a bottom surface of the first sub-source/drain pattern to a side surface of a lowermost one of the inner electrodes, and
wherein the second lower insulating pattern is extended from an upper portion of a side surface of the backside active contact to a side surface of a lowermost one of the inner electrodes.

19. The semiconductor device of claim 18, wherein the first lower insulating pattern includes SiNₓ, SiOC, SiOCN, SION, SIO, SiBCN, SiBC, or combinations thereof,
wherein the second lower insulating pattern includes SiNₓ, SiOC, SiOCN, SiON, SiO, SiBCN, SiBC, or combinations thereof,
wherein the etch stop layer comprises SiN, SiCN, SiOCN, SiBN, SiBC, or combinations thereof, and
wherein a hardness of the etch stop layer is greater than a hardness of the first lower insulating pattern and a hardness of the second lower insulating pattern.

20. The semiconductor device of claim 18, further comprising:
an inner spacer disposed between the inner electrodes of the gate electrode and each of the first sub-source/drain pattern and second sub-source/drain pattern,
wherein each of the first sub-source/drain pattern and second sub-source/drain pattern comprises a plurality of stacking faults.
